(19) United States
(12) Patent Application Publication
(10) Pub. No.: US 2024/0203931 A1
(43) Pub. Date: Jun. 20, 2024

(54) SEMICONDUCTOR DEVICE, DRIVE DEVICE FOR SEMICONDUCTOR DEVICE, MANUFACTURING METHOD FOR SEMICONDUCTOR DEVICE

(71) Applicant: ROHM CO., LTD., Kyoto-shi (JP)

(72) Inventor: Hirokatsu UMEGAMI, Kyoto-shi (JP)

(21) Appl. No.: 18/420,253

(22) Filed: Jan. 23, 2024

Related U.S. Application Data
(63) Continuation of application No. PCT/JP2022/032206, filed on Aug. 26, 2022.

(30) Foreign Application Priority Data
Sep. 17, 2021 (JP) 2021-151834

(51) Int. Cl. H01L 23/00; H01L 23/34; H01L 23/373

(52) U.S. Cl. CPC H01L 24/48; H01L 23/34; H01L 23/3735; H01L 24/45; H01L 24/85; H01L 2224/45147; H01L 2224/45155; H01L 2224/48227; H01L 2224/4903; H01L 2224/85447

(57) ABSTRACT

A semiconductor device includes a semiconductor element, a first wire, a second wire, and a metal portion. The semiconductor element includes an element obverse surface and an element reverse surface facing away from each other in a thickness direction, and an electrode disposed on the element obverse surface. The first wire contains a first metal. The second wire contains a second metal having a thermoelectric power different from that of the first metal. The metal portion contains a third metal and is disposed such that heat from the semiconductor element is conducted thereto. The first wire and the second wire are bonded to the metal portion. At least one of the first wire and the second wire is directly bonded to the metal portion.

### TECHNICAL FIELD

The present disclosure relates to a semiconductor device, a drive device for the semiconductor device, and a method for manufacturing the semiconductor device.

### BACKGROUND ART

Some semiconductor devices include a temperature sensor for detecting the temperature of a semiconductor element. JP-A-2019-212930 discloses forming a temperature detection element near a pad of a transistor in a power transistor formation region. In the case of a semiconductor element that cannot have a large chip area, however, it is difficult to form a temperature sensor inside the element. JP-A-2021-86933 discloses a semiconductor device in which a temperature detection element is disposed in contact with an insulating layer near a semiconductor element. In such a case, however, the temperature is detected based on the heat conducted through the insulating layer and the mounting layer on which the semiconductor element is mounted, which leads to reduced accuracy of the detected temperature of the semiconductor element.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1, as seen through a resin member.

FIG. 3 is an enlarged view of a part of FIG. 2.

FIG. 4 is a sectional view taken along line IV-IV in FIG. 2.

FIG. 5 is a sectional view taken along line V-V in FIG. 2.

FIG. 6 is a sectional view taken along line VI-VI in FIG. 3.

FIG. 7 is a perspective view showing the state in which a drive device is attached to the semiconductor device shown in FIG. 1.

FIG. 8 is a circuit diagram showing an example of the circuit configuration of the semiconductor device shown in FIG. 1.

FIG. 9 is a flow chart of an example of a method for manufacturing the semiconductor device shown in FIG. 1.

FIG. 10 is a sectional view showing a step of an example of a method for manufacturing the semiconductor device shown in FIG. 1.

FIG. 11 is a sectional view showing a step of an example of a method for manufacturing the semiconductor device shown in FIG. 1.

FIG. 12 is a sectional view showing a step of an example of a method for manufacturing the semiconductor device shown in FIG. 1.

FIG. 13 is a sectional view showing a step of an example of a method for manufacturing the semiconductor device shown in FIG. 1.

FIG. 14 is a sectional view showing a step of an example of a method for manufacturing the semiconductor device shown in FIG. 1.

FIG. 15 is a sectional view showing a step of an example of a method for manufacturing the semiconductor device shown in FIG. 1.

FIG. 16 is a partially enlarged plan view of a semiconductor device according to a first variation of the first embodiment.

FIG. 17 is a partially enlarged plan view of a semiconductor device according to a second variation of the first embodiment.

FIG. 18 is a partially enlarged plan view of a semiconductor device according to a third variation of the first embodiment.

FIG. 19 is a sectional view taken along line XIX-XIX in FIG. 18.

FIG. 20 is a plan view of a semiconductor device according to a second embodiment of the present disclosure, as seen through a resin member.

FIG. 21 is a plan view of a semiconductor device according to a third embodiment of the present disclosure, as seen through a resin member.

FIG. 22 is a circuit diagram showing an example of the circuit configuration of the semiconductor device shown in FIG. 21.

FIG. 23 is a partially enlarged plan view of a semiconductor device according to a fourth embodiment of the present disclosure, as seen through a resin member.

FIG. 24 is a sectional view taken along line XXIV-XXIV in FIG. 23.

FIG. 25 is a circuit diagram showing an example of the circuit configuration of the semiconductor device shown in FIG. 23.

FIG. 26 is a circuit diagram showing an example of the circuit configuration of a semiconductor device according to a fifth embodiment of the present disclosure.

FIG. 27 is a plan view of a semiconductor device according to a sixth embodiment of the present disclosure, as seen through a resin member.

FIG. 28 is a plan view of a semiconductor device according to a first variation of the sixth embodiment, as seen through the resin member.

### DETAILED DESCRIPTION OF EMBODIMENTS

The following describes preferred embodiments of the present disclosure in detail with reference to the drawings.

### First Embodiment

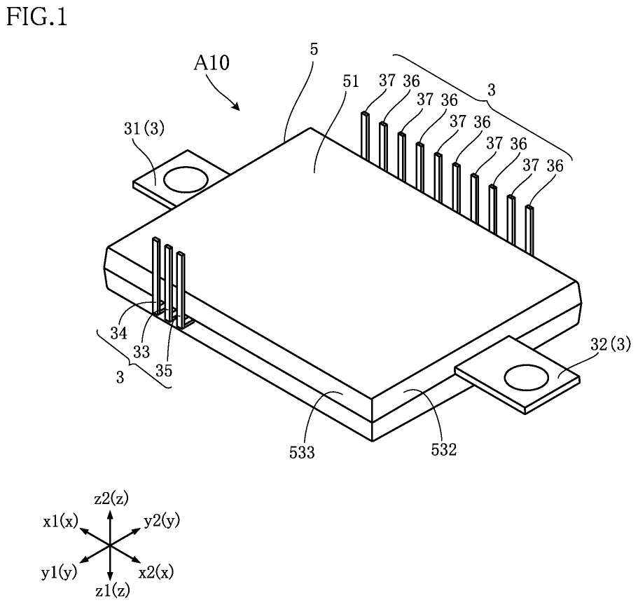

A semiconductor device A10 according to a first embodiment of the present disclosure is described below based on FIGS. 1 to 8. The semiconductor device A10 includes a plurality of semiconductor elements 11, a plurality of semiconductor elements 12, a support member 2, a plurality of terminals 3, a plurality of connecting members 41 to 47, and a resin member 5. The plurality of terminals 3 include power terminals 31 and 32, a signal terminal 33, detection terminals 34 and 35, and temperature detection terminals 36 and 37. The semiconductor device A10 is used with a drive device 7 attached thereto.

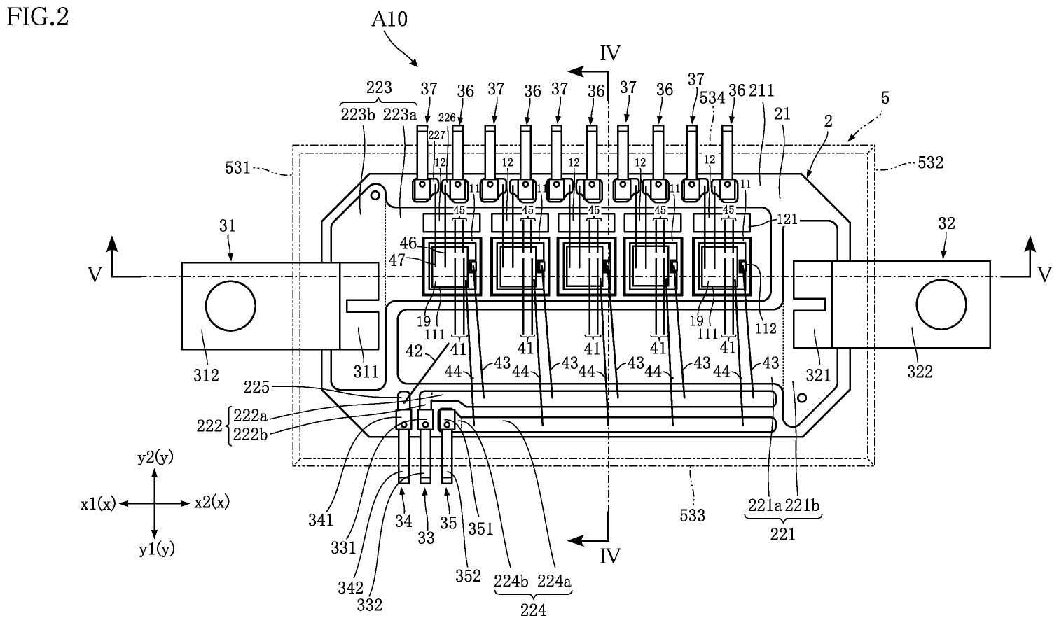

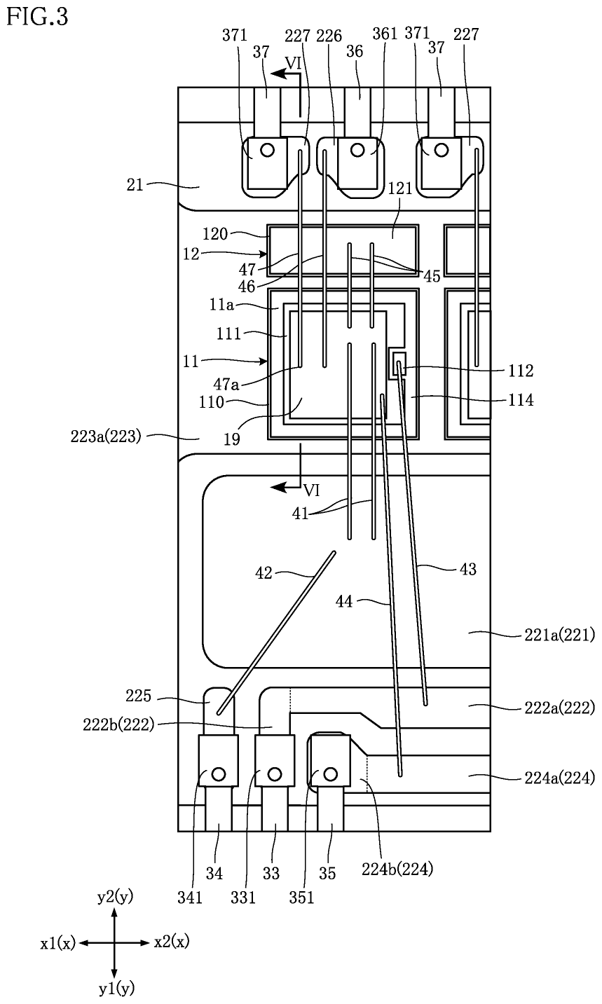

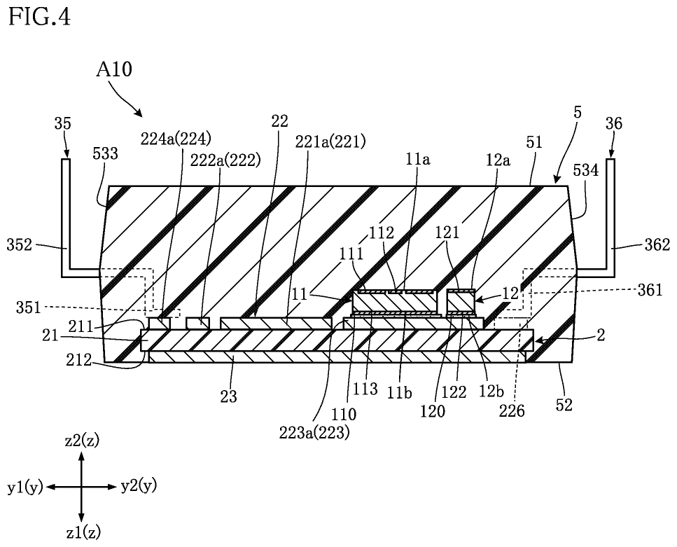

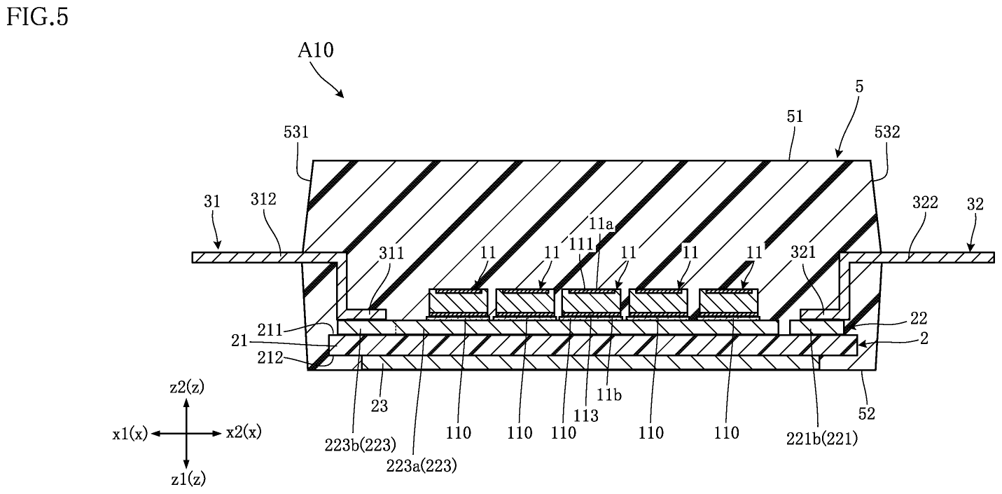

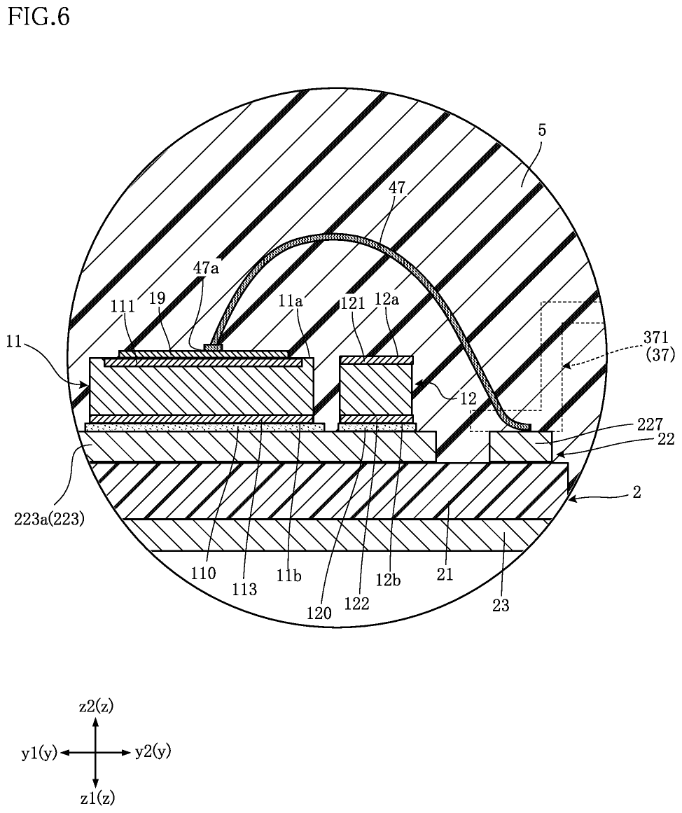

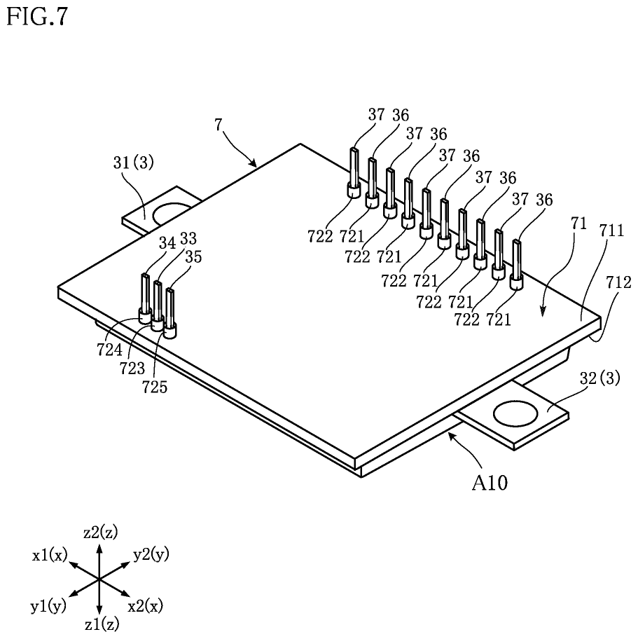

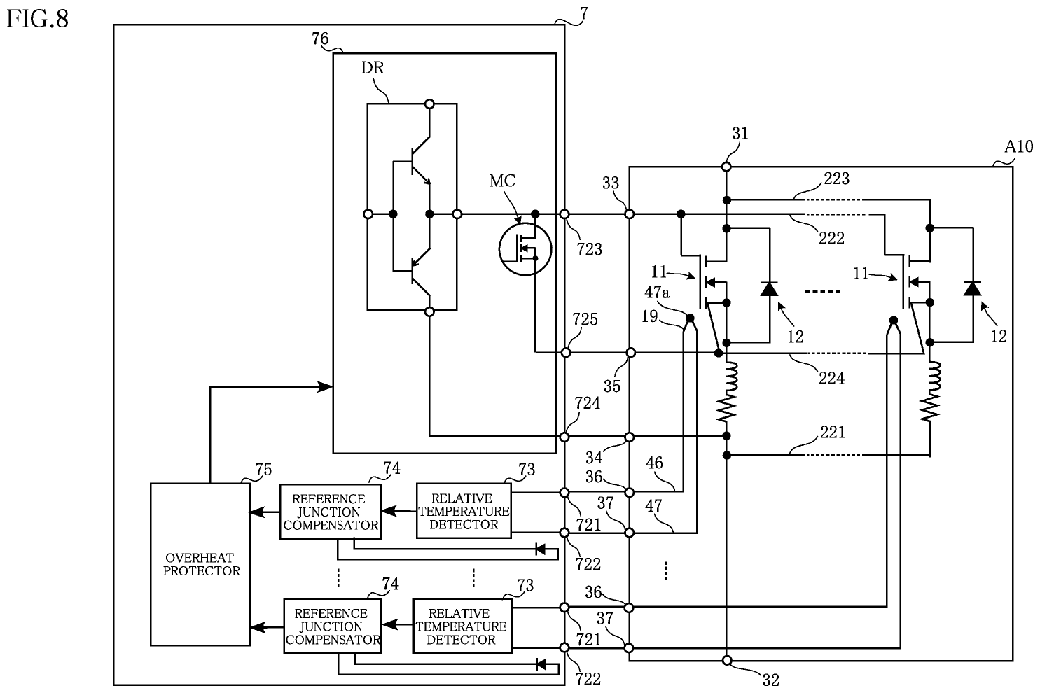

FIG. 1 is a perspective view of the semiconductor device A10. FIG. 2 is a plan view of the semiconductor device A10. For the convenience of understanding, FIG. 2 shows the resin member 5 as transparent, indicating the outlines of the resin member 5 by imaginary lines (double dashed lines). FIG. 3 is an enlarged view of a part of FIG. 2. FIG. 4 is a sectional view taken along line IV-IV in FIG. 2. FIG. 5 is a sectional view taken along line V-V in FIG. 2. The connecting members 41 to 47 are omitted in FIGS. 4 and 5. FIG. 6 is a sectional view taken along line VI-VI in FIG. 3. FIG. 7 is a perspective view showing the state in which the drive device 7 is attached to the semiconductor device A10. FIG. 8 is a circuit diagram showing an example of the circuit configuration of the semiconductor device A10.

The part of the semiconductor device A10 that is covered with the resin member 5 is rectangular as viewed in the thickness direction (also referred to as “in plan view”). For the convenience of description, the thickness direction of the semiconductor device A10 is defined as a z direction, the direction which is orthogonal to the z direction and in which power terminals 31 and 32 of the semiconductor device A10 protrude (the horizontal direction in FIG. 2) is defined as an x direction, and the direction orthogonal to the z direction and the x direction (the vertical direction in FIG. 2) is defined as a y direction. The dimensions of the semiconductor device A10 are not particularly limited.

The semiconductor elements 11 are the components that perform the electrical functions of the semiconductor device A10. Each semiconductor element 11 is made by using a semiconductor material mainly composed of SiC (silicon carbide), for example. The semiconductor material is not limited to SiC and may be Si (silicon), GaAs (gallium arsenide), or GaN (gallium nitride), for example. Each semiconductor element 11 is a switching element such as a MOSFET (Metal-Oxide-Semiconductor Field-Effect Transistor). Each semiconductor element 11 is not limited to a MOSFET, and may be a field effect transistor including a MISFET (Metal-Insulator-Semiconductor FET), or a bipolar transistor such as an IGBT (Insulated Gate Bipolar Transistor). The semiconductor elements 11 are each an n-channel MOSFET, for example, and are all the same element. Each semiconductor element 11 may be a p-channel MOSFET.

As shown in FIGS. 2 and 5, the semiconductor elements 11 are arranged at equal intervals in the x direction and connected in parallel to each other. In the present embodiment, the semiconductor device A10 includes five semiconductor elements 11 as shown in FIG. 2. The number of semiconductor elements 11 is not limited to this, and can be set freely according to the performance required of the semiconductor device A10. Each semiconductor element 11 is bonded to the support member 2 with a conductive bonding material 110. The conductive bonding material 110 is, for example, solder, silver paste or sintered metal.

Each semiconductor element 11 has an element obverse surface 11a and an element reverse surface 11b. The element obverse surface 11a and the element reverse surface 11b face away from each other in the z direction. The element obverse surface 11a faces the z2 side in the z direction. The element reverse surface 11b faces the z1 side in the z direction. The element reverse surface 11b faces the support member 2.

Each semiconductor element 11 also has a first electrode 111, a second electrode 112, and a third electrode 113. The first electrode 111 and the second electrode 112 are disposed on the element obverse surface 11a. The first electrode 111 is larger than the second electrode 112 in plan view. The third electrode 113 is disposed on the element reverse surface 12b. The third electrode 113 covers the entire surface (or substantially the entire surface) of the element reverse surface 11b. The constituent material of the first electrode 111, the second electrode 112 and the third electrode 113 is not limited, but is Al in the present embodiment. In each semiconductor element 11 that is a MOSFET, the first electrode 111 is a source electrode, the second electrode 112 is a gate electrode, and the third electrode 113 is a drain electrode. The third electrode 113 is conductively bonded to a part of the support member 2 (the conductor layer 223 of an obverse metal layer 22, described later) via a conductive bonding material 110. The third electrode 113 is in contact with the conductive bonding material 110.

Each semiconductor element 11 has a metal plate 19 bonded to the first electrode 111. The metal plate 19 is electrically connected to the first electrode 111 and is disposed such that heat from the semiconductor element 11 is properly conducted thereto. The connecting members 41 and 44 to 47 are bonded to the metal plate 19. The metal plate 19 contains a third metal. In the present embodiment, the third metal is Cu. The metal plate 19 is, for example, a clad material in which a thin plate made of Al is bonded to a surface of a plate made of Cu. The metal plate 19 is bonded to the first electrode 111 by, for example, solid-phase diffusion, with the A1 surface facing the first electrode 111 (Al). The configuration of the metal plate 19 and the method for bonding to the first electrode 111 are not limited. For example, the metal plate 19 may be made by forming a layer of Al on a surface of a plate made of Cu by sputtering or other methods.

The semiconductor elements 12 are, for example, diodes such as Schottky barrier diodes. As shown in FIG. 8, each semiconductor element 12 is connected in inverse parallel to a semiconductor element 11.

Each semiconductor element 12 is bonded to the support member 2 with a conductive bonding material 120. The conductive bonding material 120 is, for example, solder, silver paste or sintered metal. The number of semiconductor elements 12 corresponds to the number of semiconductor elements 11. Note that the semiconductor device A10 may not include the semiconductor elements 12.

Each semiconductor element 12 has an element obverse surface 12a and an element reverse surface 12b. The element obverse surface 12a and the element reverse surface 12b face away from each other in the z direction. The element obverse surface 12a faces the z2 side in the z direction. The element reverse surface 12b faces the z1 side in the z direction. The element reverse surface 12b faces the support member 2.

Each semiconductor element 12 has an anode electrode 121 and a cathode electrode 122. The anode electrode 121 is disposed on the element obverse surface 12a. The cathode electrode 122 is disposed on the element reverse surface 12b. The cathode electrode 122 is electrically connected to a part of the support member 2 (the conductor layer 223 of the obverse metal layer 22, described later) via a conductive bonding material 120. The cathode electrode 122 is in contact with the conductive bonding material 110.

The support member 2 supports the semiconductor elements 11 and 12 and provides electrical conduction paths between the semiconductor elements 11 and terminals 3. The support member 2 includes an insulating substrate 21, an obverse metal layer 22, and a reverse metal layer 23.

The insulating substrate 21 is, for example, a flat plate and has an electrically insulating property. The constituent material of the insulating substrate 21 is, for example, a ceramic material with excellent thermal conductivity, and is Al₂O₃ (aluminum oxide) in the present embodiment. The constituent material of the insulating substrate 21 is not limited and may be other ceramic materials such as AlN (aluminum nitride) or SiN (silicon nitride), for example. The constituent material of the insulating substrate 21 is not limited to a ceramic material and may be Si or a synthetic resin. The constituent material of the insulating substrate 21 may be any material as long as it has an insulating property and is capable of withstanding the heat generated by the semiconductor elements 11.

The insulating substrate 21 has an obverse surface 211 and a reverse surface 212. The obverse surface 211 and the reverse surface 212 face away from each other in the z direction. The obverse surface 211 faces the z2 side in the z direction. The reverse surface 212 faces the z1 side in the z direction.

The obverse metal layer 22 is formed on the obverse surface 211 of the insulating substrate 21. The constituent material of the obverse metal layer 22 is a metal, such as Cu or an alloy containing Cu. The constituent material of the obverse metal layer 22 is not limited. The obverse metal layer 22 is formed by plating, for example. The method for forming the obverse metal layer 22 is not limited. The obverse metal layer 22 is covered with the resin member 5. The obverse metal layer 22 includes conductor layers 221 to 225, a plurality of conductor layers 226, and a plurality of conductor layers 227. The conductor layers 221 to 227 are spaced apart from each other.

The conductor layer 221 includes a strip portion 221a and a terminal bond portion 221b. The strip portion 221a extends along the x direction. The connecting members 41 and the connecting member 42 are bonded to the strip portion. The terminal bond portion 221b is connected to an end of the strip portion 221a on the x2 side in the x direction. A portion of the power terminal 32 (the pad portion 321, described later) is bonded to the terminal bond portion.

The conductor layer 222 includes a strip portion 222a and a terminal bond portion 222b. The strip portion 222a extends along the x direction. The connecting members 43 are bonded to the strip portion. The terminal bond portion 222b is connected to an end of the strip portion 222a on the x1 side in the x direction. A portion of the signal terminal 33 (the pad portion 331, described later) is bonded to the terminal bond portion.

The conductor layer 223 includes a strip portion 223a and a terminal bond portion 223b. The strip portion 223a extends along the x direction. The semiconductor elements 11 and 12 are bonded to the strip portion. The heat from each semiconductor element 11 is properly conducted to the strip portion 223a (the conductor layer 223) via the conductive bonding material 110. The semiconductor elements 11 bonded to the strip portion 223a are aligned in the direction (the x direction) in which the strip portion 223a extends. The terminal bond portion 223b is connected to an end of the strip portion 223a on the x1 side in the x direction. A portion of the power terminal 31 (the pad portion 311, described later) is bonded to the terminal bond portion. As shown in FIGS. 4 and 5, the conductor layer 223 is electrically connected to the third electrode 113 (the drain electrode) of each semiconductor element 11 via a conductive bonding material 110 and to the cathode electrode 122 of each semiconductor element 12 via a conductive bonding material 120. That is, the third electrode 113 of each semiconductor element 11 and the cathode electrode 122 of each semiconductor element 12 are electrically connected to each other via the conductor layer 223.

The conductor layer 224 includes a strip portion 224a and a terminal bond portion 224b. The strip portion 224a extends along the x direction. The connecting members 44 are bonded to the strip portion. The terminal bond portion 224b is connected to an end of the strip portion 224a on the x1 side in the x direction. A portion of the detection terminal 35 (the pad portion 351, described later) is bonded to the terminal bond portion.

The connecting member 42 is bonded tot he conductor layer 225. A portion of the detection terminal 34 (the pad portion 341, described later) is bonded to the conductor layer 225.

The strip portions 221a, 222a, 223a and 224a of the obverse metal layer 22 are arranged side by side in the y direction and overlap with each other as viewed in the y direction. The order in which the strip portions 221a, 222a, 223a and 224a are arranged in the y direction is not particularly limited. In the present embodiment, the strip portion 224a, the strip portion 222a, the strip portion 221a, and the strip portion 223a are arranged in this order from the y1 side toward the y2 side in the y direction, as shown in FIGS. 2 and 3. Thus, the strip portion 221a is located between the strip portion 222a and the strip portion 223a in the y direction, and the strip portion 222a is located between the strip portion 221a and the strip portion 224a in the y direction. The strip portion 223a is located opposite to the strip portion 222a with the strip portion 221a interposed therebetween in the y direction. The conductor layer 225 is disposed on the x1 side in the x direction of the terminal bond portion 222b of the conductor layer 222.

The conductor layers 226 and the conductor layers 227 are disposed on the y2 side in the y direction of the strip portion 223a. The obverse metal layer 22 includes the same number of conductor layers 226 and conductor layers 227 as the semiconductor elements 11 (five in the present embodiment). The conductor layers 226 and the conductor layers 227 are alternately arranged along the x direction. A connecting member 46 is bonded to each conductor layer 226. A portion of the temperature detection terminal 36 (the pad portion 361, described later) is bonded to each conductor layer 226. A connecting member 47 is bonded to each conductor layer 227. A portion of the temperature detection terminal 37 (the pad portion 371, described later) is bonded to each conductor layer 227.

The arrangement and shape of the conductor layers 221 to 227 are not limited to those described above and may be designed as appropriate depending on the arrangement of the terminals 3 or the like.

The reverse metal layer 23 is formed on the reverse surface 212 of the insulating substrate 21. The constituent material of the reverse metal layer 23 is a metal, such as Cu or an alloy containing Cu. The constituent material is not limited. The reverse metal layer 23 is formed by electroless plating, for example. The method for forming the reverse metal layer 23 is not limited. As shown in FIGS. 4 and 5, the surface of the reverse metal layer 23 facing the z1 side in the z direction is exposed from the resin member 5. Note however that the surface facing the z1 side in the z direction may be covered with the resin member 5. The support member 2 may not include the reverse metal layer 23. In such a case, the reverse surface 212 of the insulating substrate 21 may be covered with the resin member 5 or may be exposed from the resin member 5.

Each terminal 3 is bonded to the obverse metal layer 22 inside the resin member 5. Each terminal 3 protrudes from the insulating substrate 21 as viewed in the z direction. Each terminal 3 is partially exposed from the resin member 5. The terminals 3 may be formed from a same lead frame. Each terminal 3 is made of a metal, and preferably made of one of Cu and Ni, an alloy of these, or 42 alloy, for example.

The power terminal 31 is a drain terminal of the semiconductor device A10. The power terminal 31 a plate-like member. The power terminal 31 is electrically connected to the third electrode 113 (the drain electrode) of each semiconductor element 11 via the conductor layer 223 and a conductive bonding material 110.

The power terminal 31 includes a pad portion 311 and a terminal portion 312. The pad portion 311 is covered with the resin member 5. The pad portion 311 is bonded to the conductor layer 223. This bonding may be performed by any method including bonding using a conductive bonding material (solder, silver paste, sintered metal, etc.), laser bonding, and ultrasonic bonding. The terminal portion 312 is exposed from the resin member 5. As shown in FIG. 2, the terminal portion 312 extends from the resin member 5 toward the x1 side in the x direction as viewed in the z direction. The surface of the terminal portion 312 may be plated with silver, for example.

The power terminal 32 is a source terminal f the semiconductor device A10. The power terminal 32 a plate-like member. The power terminal 32 is electrically connected to the first electrode 111 (the source electrode) of each semiconductor element 11 via the conductor layer 221, the connecting members 41, and the metal plates 19.

The power terminal 32 includes a pad portion 321 and a terminal portion 322. The pad portion 321 is covered with the resin member 5. The pad portion 321 is bonded to the conductor layer 221. This bonding may be performed by any method including bonding using a conductive bonding material (solder, silver paste, sintered metal, etc.), laser bonding, and ultrasonic bonding. The terminal portion 322 is exposed from the resin member 5. As shown in FIG. 2, the terminal portion 322 extends from the resin member 5 toward the x2 side in the x direction as viewed in the z direction. The surface of the terminal portion 322 may be plated with silver, for example.

The signal terminal 33 is a gate terminal of the semiconductor device A10. The signal terminal 33 is electrically connected to the second electrode 112 (the gate electrode) of each semiconductor element 11 via the conductor layer 222 and the connecting members 43. The signal terminal 33 receives a drive signal for on/off control of each semiconductor element 11. As shown in FIG. 8, to the signal terminal 33 is connected a drive circuit DR, for example. The drive circuit DR generates a drive signal that controls the switching operation of each semiconductor element 11. The drive signal is inputted from the drive circuit DR to the signal terminal 33. The drive circuit DR shown in FIG. 8 is one example, and the drive circuit is not limited to the illustrated circuit configuration.

The signal terminal 33 includes a pad portion 331 and a terminal portion 332. The pad portion 331 is covered with the resin member 5. The pad portion 331 is bonded to the conductor layer 222. This bonding may be performed by any method including bonding using a conductive bonding material, laser bonding, and ultrasonic bonding. The terminal portion 332 is exposed from the resin member 5. The terminal portion 332 is L-shaped as viewed in the x direction.

The detection terminal 34 is a source sense terminal of the semiconductor device A10. The detection terminal 34 is electrically connected to the first electrode 111 (the source electrode) of each semiconductor element 11 via the conductor layer 225, the connecting member 42, the conductor layer 221, the connecting members 41, and the metal plates 19. As shown in FIG. 8, to the detection terminal 34 is connected a drive circuit DR, for example. The voltage applied to the detection terminal 34 is inputted to the drive circuit DR as a feedback signal.

The detection terminal 34 includes a pad portion 341 and a terminal portion 342. The pad portion 341 is covered with the resin member 5. The pad portion 341 is bonded to the conductor layer 225. This bonding may be performed by any method including bonding using a conductive bonding material, laser bonding, and ultrasonic bonding. The terminal portion 342 is exposed from the resin member 5. The terminal portion 342 is L-shaped as viewed in the x direction.

The detection terminal 35 is a source sense terminal of the semiconductor device A10. The detection terminal 35 is electrically connected to the first electrode 111 (the source electrode) of each semiconductor element 11 via the conductor layer 224, the connecting members 44, and the metal plates 19. Between the detection terminal 35 and the signal terminal 33 may be connected a mirror clamp circuit MC external to the semiconductor device A10, as shown in FIG. 8. The mirror clamp circuit MC is a circuit to prevent malfunction (accidental “ON” of the gate) of the semiconductor elements 11, and includes, for example, a MOSFET, as shown in FIG. 8. The source terminal of the MOSFET is connected to the detection terminal 35, and the drain terminal of the MOSFET is connected to the signal terminal 33. When a semiconductor element 11 is off, the MOSFET of the mirror clamp circuit MC is turned on to forcibly make the gate-source voltage of the semiconductor element 11 0 (zero) V (or approximately 0 V) or a negative bias voltage, thereby suppressing the rise of the gate potential of the semiconductor element 11.

The detection terminal 35 includes a pad portion 351 and a terminal portion 352. The pad portion 351 is covered with the resin member 5. The pad portion 351 is bonded to the conductor layer 224. This bonding may be performed by any method including bonding using a conductive bonding material, laser bonding, and ultrasonic bonding. The terminal portion 352 is exposed from the resin member 5. As shown in FIG. 4, the terminal portion 352 is L-shaped as viewed in the x direction.

The detection terminal 34, the signal terminal 33, and the detection terminal 35 are aligned in this order from the x1 side toward the x2 side along the x direction as shown in FIGS. 2 and 3, and overlap with each other as viewed in the x direction as shown in FIG. 4. The detection terminal 34, the signal terminal 33, and the detection terminal 35 protrude from a resin side surface 533 on the y1 side in the y direction.

The temperature detection terminals 36 and 37 are terminals for detecting the temperature of the semiconductor elements 11. One temperature detection terminal 36 and one temperature detection terminal 37 are provided for each semiconductor element 11. Since the semiconductor device A10 includes five semiconductor elements 11 in the present embodiment, five temperature detection terminals 36 and five temperature detection terminals 37 are provided. Each temperature detection terminal 36 is bonded to a conductor layer 226. Each temperature detection terminal 36 is electrically connected to a connecting member 46 via a conductor layer 226. Each temperature detection terminal 37 is bonded to a conductor layer 227. Each temperature detection terminal 37 is electrically connected to a connecting member 47 via a conductor layer 227.

Each temperature detection terminal 36 includes a pad portion 361 and a terminal portion 362. The pad portion 361 is covered with the resin member 5. The pad portion 361 is bonded to the conductor layer 226. This bonding may be performed by any method including bonding using a conductive bonding material, laser bonding, and ultrasonic bonding. The terminal portion 362 is exposed from the resin member 5. As shown in FIG. 4, the terminal portion 362 is L-shaped as viewed in the x direction. Each temperature detection terminal 37 includes a pad portion 371 and a terminal portion 372. The pad portion 371 is covered with the resin member 5. The pad portion 371 is bonded to the conductor layer 227. This bonding may be performed by any method including bonding using a conductive bonding material, laser bonding, and ultrasonic bonding. The terminal portion 372 is exposed from the resin member 5. The terminal portion 372 is L-shaped as viewed in the x direction.

The temperature detection terminals 36 and the temperature detection terminals 37 are alternately arranged along the x direction as shown in FIGS. 2 and 3, and overlap with each other as viewed in the x direction as shown in FIG. 4. The temperature detection terminals 36 and 37 protrude from a resin side surface 534 on the y2 side in the y direction.

Each of the connecting members 41 to 45 electrically connects two separated parts to each other. Each connecting member 41 to 45 is a so-called bonding wire. In the present embodiment, the connecting members 41 to 45 are formed by wedge bonding. The connecting members 41 to 45 may be formed by ball bonding. The constituent material of the connecting members 41 to 45 is Al, Au, Cu or an alloy containing one of these, for example, and is not limited. The present embodiment describes the case where the constituent material of the connecting members 41 to 45 is Cu.

Each connecting member 41 is bonded to a metal plate 19 at one end and bonded to the conductor layer 221 at the other end. Each connecting member 41 electrically connects the first electrode 111 (the source electrode) of each semiconductor element 11 and the conductor layer 221 to each other.

The connecting member 42 is bonded to the conductor layer 221 at one end and bonded to the conductor layer 225 at the other end. The connecting member 42 electrically connects the conductor layer 221 and the conductor layer 225 to each other. The above-mentioned other end of the connecting member 42 may not be bonded to the conductor layer 225 but may be bonded to the pad portion 341 of the detection terminal 34.

Each connecting member 43 is connected to the second electrode 112 (the gate electrode) of a semiconductor element 11 at one end and bonded to the conductor layer 222 at the other end. Each connecting member 43 electrically connects the second electrode 112 and the conductor layer 222 to each other.

Each connecting member 44 is bonded to a metal plate 19 at one end and bonded to the conductor layer 224 at the other end. Each connecting member 44 electrically connects the first electrode 111 (the source electrode) of a semiconductor element 11 and the conductor layer 224 to each other. Each connecting member 44 is a sense wire connected to the first electrode 111 (the source electrode) of a semiconductor element 11 by Kelvin connection.

Each connecting member 45 is bonded to a metal plate 19 at one end and bonded to the anode electrode 121 of a semiconductor element 12 at the other end. Each connecting member 45 electrically connects the first electrode 111 (the source electrode) of a semiconductor element 11 and the anode electrode 121 of a semiconductor element 12 to each other.

The connecting members 46 and 47 are members for detecting the temperature of the semiconductor elements 11. The connecting members 46 and 47 are provided by the method for forming a bonding wire, as with the connecting members 41 to 45. In the present embodiment, the connecting members 46 and 47 are formed by wedge bonding. The connecting members 46 and 47 may be formed by ball bonding. Each connecting member 46 is bonded to a metal plate 19 at one end and bonded to a conductor layer 226 at the other end. Each connecting member 47 is bonded to a metal plate 19 at one end and bonded to a conductor layer 227 at the other end. The connecting members 46 and 47 are both directly bonded to the metal plates 19. That is, the connecting members 46 and 47 and the metal plates 19 are in direct contact with each other with no other members interposed therebetween. On each metal plate 19, the connecting member 46 and the connecting member 47 are bonded in a mutually spaced manner.

The constituent material of the connecting members 46 is a first metal. In the present embodiment, the first metal is the same as the third metal, which is Cu. The constituent material of the connecting members 47 is a second metal having a thermoelectric power different from that of the first metal. Thermoelectric power refers to the thermoelectromotive force per 1K produced when a temperature difference is created between opposite ends of electrically conductive material. In the present embodiment, the second metal is constantan (a copper-nickel alloy: 55Cu-45Ni). A connecting member 46 and a metal plate 19 (Cu) together with a connecting member 47 (constantan) function as a thermocouple. Thermocouples made of Cu and constantan are widely known as a T-type thermocouple. The junction 47a between the connecting member 47 and the metal plate 19 corresponds to the measuring junction (hot junction) of the thermocouple. The junction between the connecting member 46 and the conductor layer 226 and the junction between the connection member 47 and the conductor layer 227 correspond to the reference junctions (cold junction) of the thermocouple. A voltage is produced between the reference junctions depending on the temperature difference between the reference junctions and the measuring junction. The temperature detection terminals 36 and 37 output the voltage between the reference junctions to the drive device 7 as a signal for detecting the temperature of the semiconductor element 11.

The resin member 5 is an electrically insulating material that seals the semiconductor elements. The resin member 5 covers the entirety of the semiconductor elements 11, the semiconductor elements 12, the insulating substrate 21, the obverse metal layer 22 and the connecting members 41 to 47, and a part of each terminal 3. The constituent material of the resin member 5 is, for example, an epoxy resin. The constituent material of the resin member 5 is not limited. The resin member 5 is formed by transfer molding using a mold, for example. The method for forming the resin member 5 is not limited. As shown in FIGS. 2, 4 and 5, the resin member 5 has a resin obverse surface 51, a resin reverse surface 52, and a plurality of resin side surfaces 531 to 534.

The resin obverse surface 51 and the resin reverse surface 52 face away from each other in the z direction. The resin obverse surface 51 faces the z2 side in the z direction, and the resin reverse surface 52 faces the z1 side in the z direction. The reverse metal layer 23 is exposed from the resin reverse surface 52. The resin reverse surface 52 and the surface of the reverse metal layer 23 that faces z1 side in the z direction are flush with each other. Each of the resin side surfaces 531 to 534 is connected to both the resin obverse surface 51 and the resin reverse surface 52 and sandwiched between these surfaces. As shown in FIG. 2, the two resin side surfaces 531 and 532 face away from each other in the x direction. The resin side surface 531 is located on the x1 side in the x direction and faces the x1 side in the x direction. The resin side surface 532 is located on the x2 side in the x direction and faces the x2 side in the x direction. The two resin side surfaces 533 and 534 face away from each other in the y direction. The resin side surface 533 is located on the y1 side in the y direction and faces the y1 side in the y direction. The resin side surface 534 is located on the y2 side in the y direction and faces the y2 side in the y direction.

The resin side surfaces 531 to 534 include surfaces connected to the resin obverse surface 51 and inclined to become closer to each other as proceeding toward the resin obverse surface 51. The portion of the resin member 5 that is defined by these inclined surfaces connected to the resin obverse surface 51 has a tapered shape of which sectional area in an x-y plane becomes smaller as proceeding toward the resin obverse surface 51. The resin side surfaces 531 to 534 include surfaces connected to the resin reverse surface 52 and inclined to become closer to each other as proceeding toward the resin reverse surface 52. The portion of the resin member 5 that is defined by these inclined surfaces connected to the resin reverse surface 52 has a tapered shape of which sectional area in an x-y plane becomes smaller as proceeding toward the resin reverse surface 52. The shape of the resin member 5 shown in FIGS. 1 to 5 is one example. The shape of the resin member 5 is not limited to the illustrated one.

Next, the drive device 7 will be described.

The drive device 7 is a device for driving the semiconductor device A10 and attached to the z2 side in the z direction of the semiconductor device A10. As shown in FIG. 7, the drive device 7 includes a substrate 71, a terminal 723, a terminal 724, a terminal 725, a plurality of terminals 721, and a plurality of terminals 722. The substrate 71 is, for example, a flat plate and has an electrically insulating property. The constituent material of the substrate 71 is not limited. The substrate 71 has an obverse surface 711 and a reverse surface 712. The obverse surface 711 and the reverse surface 712 face away from each other in the z direction. The obverse surface 711 faces the z2 side in the z direction. The reverse surface 712 faces the z1 side in the z direction. The obverse surface 711 has wiring formed thereon, and external connectors, a number of electronic components and the like are mounted on the obverse surface 711. The wiring, external connectors and electronic components on the obverse surface 711 are omitted in FIG. 7.

Each of the terminals 721 to 725 is a cylindrical metal member and inserted in a through-hole penetrating the substrate 71 from the obverse surface 711 to the reverse surface 712 in the z direction. The terminals 721 to 725 are electrically connected to the wiring formed on the obverse surface 711. The terminal portions 332, 342, 352, 362 and 372 of the terminals 33 to 37 of the semiconductor device A10 are inserted into the terminals 721 to 725 and bonded with solder, for example. As shown in FIGS. 7 and 8, the signal terminal 33 is bonded to the terminal 723. The detection terminal 34 is bonded to the terminal 724. The detection terminal 35 is bonded to the terminal 725. Five terminals 721 are disposed to correspond to the five temperature detection terminals 36, and the temperature detection terminals 36 are bonded to the terminals 721, respectively. Since the temperature detection terminals 36 are electrically connected to the connecting members 46 via the conductor layers 226, the terminals 721 are electrically connected to the connecting members 46. Five terminals 722 are disposed to correspond to the five temperature detection terminals 37, and the temperature detection terminals 37 are bonded to the terminals 722, respectively. Since the temperature detection terminals 37 are electrically connected to the connecting members 47 via the conductor layers 227, the terminals 722 are electrically connected to the connecting members 47.

As shown in FIG. 8, the drive device 7 includes, as its functional components, a plurality of relative temperature detectors 73, a plurality of reference junction compensators 74, an overheat protector 75, and a drive controller 76. The drive controller 76 functions to control the switching operation of each semiconductor element 11 and is realized by a gate drive IC, for example. The drive controller 76 includes circuits such as a drive circuit DR and a mirror clamp circuit MC. The drive controller 76 generates a drive signal based on a control signal inputted from the outside and outputs the drive signal to the semiconductor device A10 through the terminal 723. The drive signal is inputted to the semiconductor device A10 through the signal terminal 33 connected to the terminal 723 to control the switching operation of each semiconductor element 11. Also, the drive controller 76 receives a signal from the detection terminal 34 of the semiconductor device A10 through the terminal 724, and receives a signal from the detection terminal 35 through the terminal 725. The specific circuit configuration and mode of the drive controller 76 are not limited.

The relative temperature detectors 73 and the reference junction compensators 74 are functional components to detect the temperature of the semiconductor elements 11. Five each of the relative temperature detectors 73 and the reference junction compensators 74 are provided correspondingly to the number of semiconductor elements 11 in the semiconductor device A10. Each relative temperature detector 73 receives a voltage from a pair of temperature detection terminals 36 and 37 of the semiconductor device A10 through a pair of terminals 721 and 722. This voltage is the voltage between the reference junctions of the thermocouple, which is formed by the connecting member 46 and the metal plate 19 together with the connecting member 47, and corresponds to the temperature difference between the reference junctions and the measuring junction. That is, this voltage corresponds to the relative temperature of the semiconductor element 11 relative to the temperature of the reference junctions. Each relative temperature detector 73 detects the relative temperature of the corresponding semiconductor element 11 based on the voltage inputted.

Each reference junction compensator 74 converts the relative temperature detected by the corresponding relative temperature detector 73 into an absolute temperature. Each reference junction compensator 74 is provided with a temperature detecting part having e.g. a diode disposed adjacent to corresponding terminals 721 and 722. The temperature detecting part may have a temperature sensor such as a thermistor. The temperature detection terminals 36 and 37, which are bonded to the terminals 721 and 722, are bonded to the conductor layers 226 and 227. The temperature detecting part detects the temperature of the terminals 721 and 722 to indirectly detect the temperature of the reference junctions of the thermocouple. The reference junction compensator 74 adds the temperature of the reference junctions detected by the temperature detecting part to the relative temperature detected by the relative temperature detector 73, thereby converting the relative temperature into an absolute temperature. Thus, each reference junction compensator 74 outputs the absolute temperature of a corresponding semiconductor element 11 to the overheat protector 75.

The specific circuit configurations of the relative temperature detectors 73 and the reference junction compensators 74 are not limited and may be as follows. Each relative temperature detector 3 transmits to a reference junction compensator 74 the voltage between a pair of terminals 721 and 722 as a voltage corresponding to the relative temperature of the corresponding semiconductor element 11. The reference junction compensator 74 converts a voltage corresponding to the temperature of the reference junctions, which is detected by the temperature detecting part, to a voltage corresponding to the thermoelectromotive force of the thermocouple, then adds the voltage to the voltage transmitted from the relative temperature detector 73, and then outputs the result to the overheat protector 75. Thus, the voltage corresponding to the absolute temperature of the semiconductor element 11 is inputted to the overheat protector 75.

The overheat protector 75 detects the overheating or abnormal temperature of each semiconductor element 11 based on the absolute temperature inputted from the corresponding reference junction compensator 74. When the absolute temperature inputted from a reference junction compensator 74 exceeds a threshold temperature, the overheat protector 75 outputs an abnormality detection signal to the drive controller 76. Upon receiving the abnormality detection signal, the drive controller 76 stops outputting the drive signal to thereby stop the operation of the semiconductor device A10. The specific circuit configuration of the overheat protector 75 is not limited. For example, the overheat protector 75 may be provided with a comparator that generates an abnormality detection signal when the voltage corresponding to the absolute temperature, inputted from the reference junction compensator 74, exceeds the voltage corresponding to the threshold temperature.

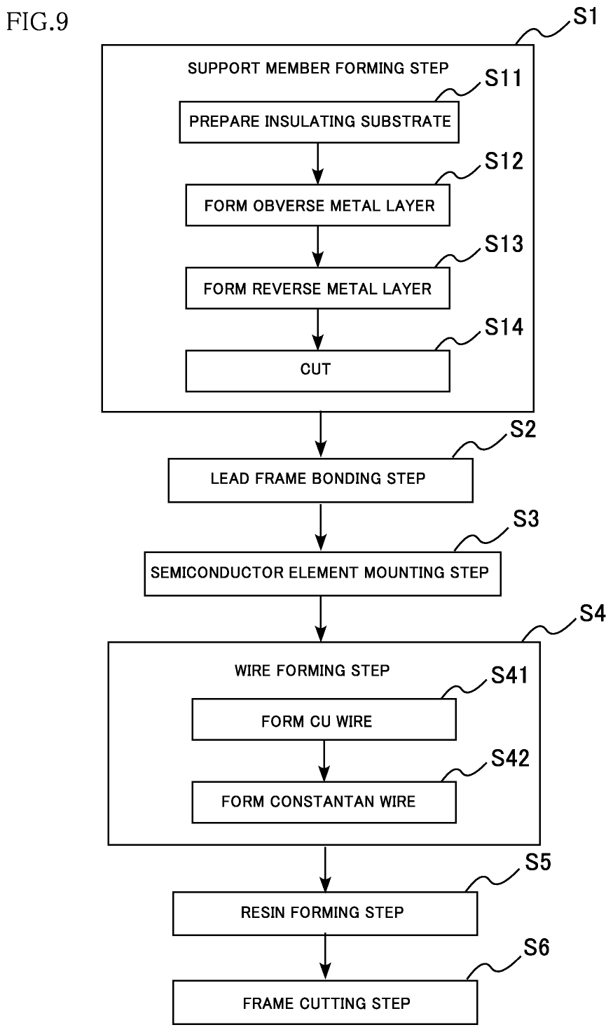

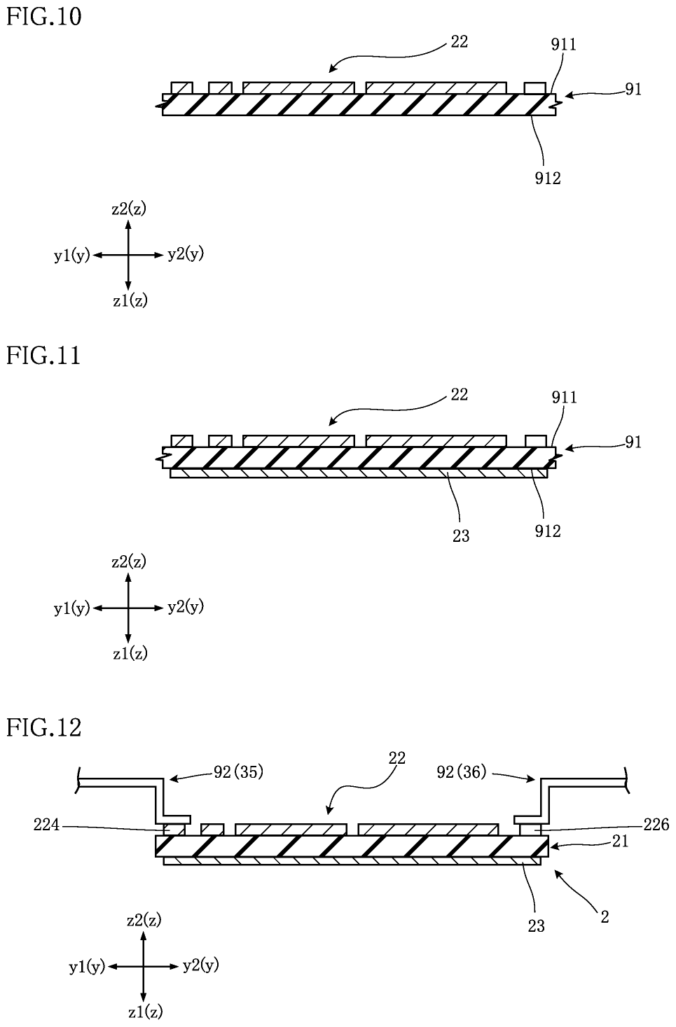

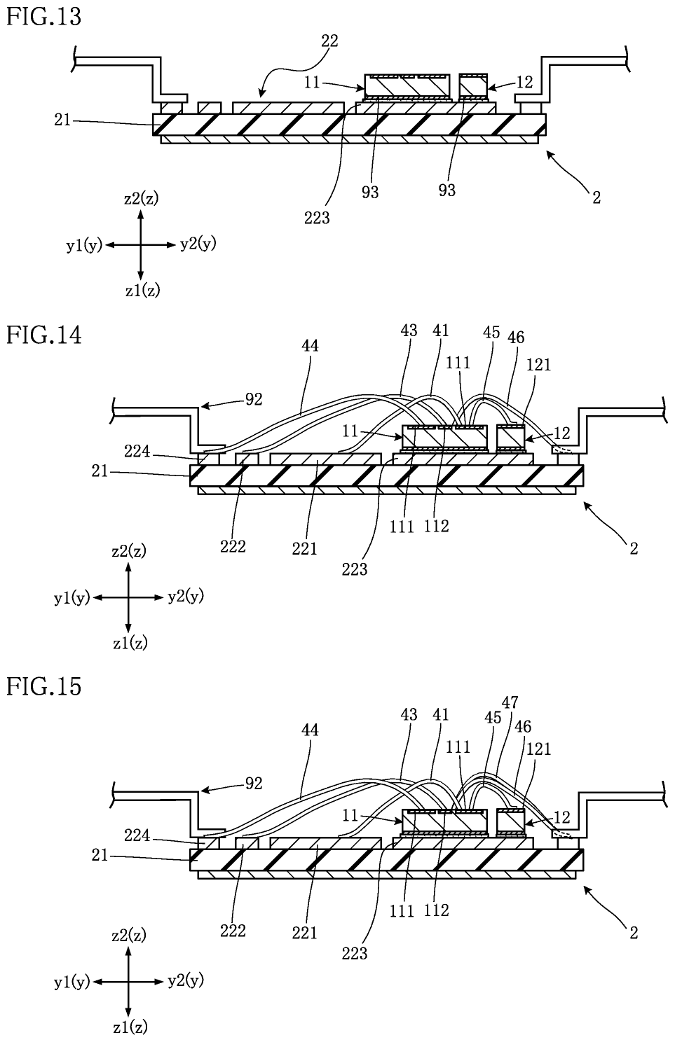

Next, an example of a method for manufacturing the semiconductor device A10 will be described with reference to FIGS. 9 to 15. The manufacturing method described below is one means for realizing the semiconductor device A10, and the present disclosure is not limited to this. FIG. 9 is a flow chart of an example of a method for manufacturing the semiconductor device A10. FIGS. 10 to 15 show steps of an example of a method for manufacturing the semiconductor device A10. FIGS. 10 to 15 are sectional views corresponding to FIG. 4. The x direction, y direction, and z direction shown in FIGS. 10 to 15 are the same as those shown in FIGS. 1 to 7.

As shown in FIG. 9, the method for manufacturing the semiconductor device A10 includes a support member forming step (S1), a lead frame bonding step (S2), a semiconductor element mounting step (S3), a wire forming step (S4), a resin forming step (S5), and a frame cutting step (S6).

The support member forming step (S1) is a step for forming the support member 2. In the support member forming step, an insulating substrate 91 is first prepared (S11). The insulating substrate 91 is made of, for example, a ceramic material and has an obverse surface 911 and a reverse surface 912 facing away from each other in the z direction. Next, the obverse metal layer 22 is formed on the obverse surface 911 of the insulating substrate 91, as shown in FIG. 10 (S12). The obverse metal layer 22 may be formed by forming a base layer covering the entire obverse surface 911 by e.g. electroless plating or sputtering, forming a mask and performing electrolytic plating to form a plating layer, and then removing unnecessary portions of the base layer by etching. Next, the reverse metal layer 23 is formed on the reverse surface 912 of the insulating substrate 91, as shown in FIG. 11 (S13). The reverse metal layer 23 is formed by electroless plating, for example. Alternatively, use may be made of a DBC (Direct Bonding Copper) plate in which Cu foil is bonded to the obverse surface 911 and the reverse surface 912 of an insulating substrate 91, and the obverse metal layer 22 and the reverse metal layer 23 may be formed on the insulating substrate 91 by patterning the Cu foil on the obverse surface 911 side. Next, the insulating substrate 91 is cut (S14). Cutting the insulating substrate 91 provides the insulating substrate 21. In this way, the support member 2 is formed.

In the lead frame bonding step (S2), a lead frame 92 that will become the terminals 3 is first prepared. The lead frame 92 includes portions that will become the terminals 3 and also includes a frame part to which the terminals 3 are connected. The shape or the like of the lead frame 92 is not limited. Next, conductive bonding paste is applied to portions of the obverse metal layer 22 to which terminals 3 will be bonded, and the portions of the lead frame 92 that will become the terminals 3 are bonded to the obverse metal layer 22, as shown in FIG. 12. For example, the portion of the lead frame 92 that will become the detection terminal 35 is bonded to the conductor layer 224. Also, the portion of the lead frame 92 that will become a detection terminal 36 is bonded to a conductor layer 226. The method for bonding the lead frame 92 is not limited.

In the semiconductor element mounting step (S3), conductive bonding paste 93 is applied to the regions of the conductor layer 223 on which semiconductor elements 11 and 12 will be placed. The conductive bonding paste 93 is, for example, solder, silver paste or sintered metal. Next, semiconductor elements 11 and semiconductor elements 12 are adhered to the conductive bonding paste, heated, and then cooled. Thus, the conductive bonding paste 93 intervening between the conductor layer 223 and the semiconductor elements 11 becomes the conductive bonding material 110, and the semiconductor elements are is bonded to the conductor layer 223 via the conductive bonding material 110. Each semiconductor element 11 has a metal plate 19 bonded in advance to the first electrode 111. The conductive bonding paste 93 intervening between the conductor layer 223 and the semiconductor elements 12 becomes the conductive bonding material 120, and the semiconductor elements 12 are bonded to the conductor layer 223 via the conductive bonding material 120.

In the wire forming step (S4), connecting members 41 to 47 are formed. First, connecting members 41 to 46 are formed by wedge bonding, as shown in FIG. 14 (S41). The connecting member 41 is formed to bond the metal plate 19 bonded to the first electrode 111 of a semiconductor element 11 and the conductor layer 221. The connecting member 43 is formed to bond the second electrode 112 of the semiconductor element 11 and the conductor layer 222. The connecting member 44 is formed to bond the metal plate 19 and the conductor layer 224. The connecting member 45 is formed to bond the metal plate 19 and the anode electrode 121 of a semiconductor element 12. The connecting member 46 is formed to bond the metal plate 19 and the conductor layer 226. Though not shown in FIG. 14, the connecting member 42 is formed to bond the conductor layer 221 and the conductor layer 225. Since the constituent material of the connecting member 46 is the same as that of the connecting members 41 to 45, which is Cu, the connecting member 46 is formed in the same step as the connecting members 41 to 45. The order of formation of the connecting members 41 to 46 is not limited. Next, the connecting member 47 is formed by wedge bonding, as shown in FIG. 15 (S42). The connecting member 47 is formed to bond the metal plate 19 and the conductor layer 227. The connecting member 47 is formed in a step different from the step of forming the connecting members 41 to 46, because its constituent material is different from that of the connecting members 41 to 46. However, the connecting member 47 is formed by the same method and using the same equipment as the connecting members 41 to 46, with the only difference being the material of the wire. The connecting member 47 may be formed before the connecting members 41 to 46 are formed. Bonding the connecting member 46 and the connecting member 47 to the metal plate 19 in the wire forming step (S4) provides a thermocouple.

In the resin forming step (S5), a part of the lead frame 92, a part of the support member 2, the semiconductor elements 11 and 12, and the connecting members 41 to 47 are enclosed in a mold. Next, liquid resin material is injected into the cavity of the mold. The resin material is then hardened to provide the resin member 5.

In the frame cutting step (S6), the lead frame 92 is cut at appropriate portions exposed from the resin member 5. Thus, the terminals 3 are separated from each other. Thereafter, a process such as bending each terminal 3 is performed as required, whereby the semiconductor device A10 described above is obtained.

Next, the effects of the semiconductor device A10 and the drive device 7 will be described.

According to the present embodiment, each semiconductor element has a metal plate 19 bonded to the first electrode 111, and the connecting members 46 and 47 are bonded to the metal plate 19 at their one ends. The material constituting the connecting members 46 is the first metal, which is the same metal as the third metal constituting the metal plate 19. The material constituting the connecting members 47 is a second metal having a thermoelectric power different from that of the first metal. A connecting member 46 and a metal plate 19 together with a connecting member 47 function as a thermocouple and are capable of detecting a temperature by using the junction 47a between the connecting member 47 and the metal plate 19 as a measuring junction of the thermocouple. The junction 47a is in contact with the metal plate 19, to which heat from the semiconductor element 11 is properly conducted. With such a configuration, the semiconductor device A10 can detect the temperature of each semiconductor element 11 more accurately than when a temperature sensor is placed near the semiconductor element 11. Thus, the semiconductor device A10 can improve the accuracy of the detected temperature of the semiconductor elements 11 without forming a temperature sensor inside each semiconductor element 11.

In the present embodiment, the first metal and the third metal are Cu, and the second metal is constantan. Thus, a connecting member 46 and a metal plate 19 (Cu) together with a connecting member 47 function (constantan) as a T-type thermocouple.

According to the present embodiment, the connecting members 46 and 47 are formed by the method for forming a bonding wire, as with the connecting members 41 to 45. Thus, the connecting members 46 and 47 can be formed using the same equipment and by the same method as the connecting members 41 to 45. In particular, since the constituent material of the connecting members 46 is the same as that of the connecting members 41 to 45, which is Cu, the connecting members 46 can be formed in the same step as the connecting members 41 to 45.

According to the present embodiment, each semiconductor element 11 has a metal plate 19 bonded to the first electrode 111. Thus, the semiconductor elements 11 are protected from impact during wedge bonding of the connecting members 41 and 44 to 47.

According to the present embodiment, the drive device 7 includes the relative temperature detectors 73 and the reference junction compensators 74. With such a configuration, the drive device 7 can convert the relative temperature of each semiconductor element 11, which is detected by the thermocouple formed by a connecting member 46 and a metal plate 19 together with a connecting member 47, into an absolute temperature and use it for overheat protection.

Although the present embodiment describes the case where the first metal constituting the connecting members 46 is copper and the second metal constituting the connecting members 47 is constantan, the present disclosure is not limited to this. Any two metals having different thermoelectric powers can be used as the first metal and the second metal. For example, the first metal may be Cu, and the second metal may be A1. Since Cu and Al have the same polarity of thermoelectric power but have different values of thermoelectric power, a connecting member 46 and a metal plate 19 (Cu) together with a connecting member 47 (Al) function as a thermocouple. Further, Al is commonly used for bonding wires, and aluminum wire is easily available at a low price as compared with constantan wire. The combination of the first metal and the second metal may be Chromel (registered trademark) (90Ni-10Cr) and Alumel (registered trademark) (94Ni-3Al-1Si-2Mg) like a K-type thermocouple, Fe and constantan like a J-type thermocouple, or Chromel and constantan like an E-type thermocouple. The combination of the first metal and the second metal is not limited to those described above.

Although the present embodiment describes the case where the first metal constituting the connecting members 46 and the third metal constituting the metal plates 19 are the same metal (Cu), the present disclosure is not limited to this. The first metal and the third metal may be different metals. In this case, however, the difference between the detected temperature and the actual temperature needs to be corrected. For higher accuracy of temperature detection, it is preferable that the third metal and the first metal (or the second metal) are the same metal.

Although the present embodiment describes the case where the connecting members 41 to 47 are all bonding wires, the present disclosure is not limited to this. Any of the connecting members 41 to 47 may be a connecting member other than a bonding wire (e.g., a metal ribbon or a connecting lead formed by bending a metal plate). For example, instead of the connecting members 41 and the connecting members 45, use may be made of connecting leads bonded to the anode electrodes 121 of the semiconductor elements 12, the first electrodes 111 of the semiconductor elements 11 and the conductor layer 221 to electrically connect these.

Although the present embodiment describes the case where the terminals 3 are all bonded to the obverse metal layer 22, the present disclosure is not limited to this. Any of the terminals 3 may be bonded to the insulating substrate 21 while being spaced apart from the obverse metal layer 22. In this case, such a terminal is electrically connected to the obverse metal layer 22 with a connecting member such as a bonding wire.

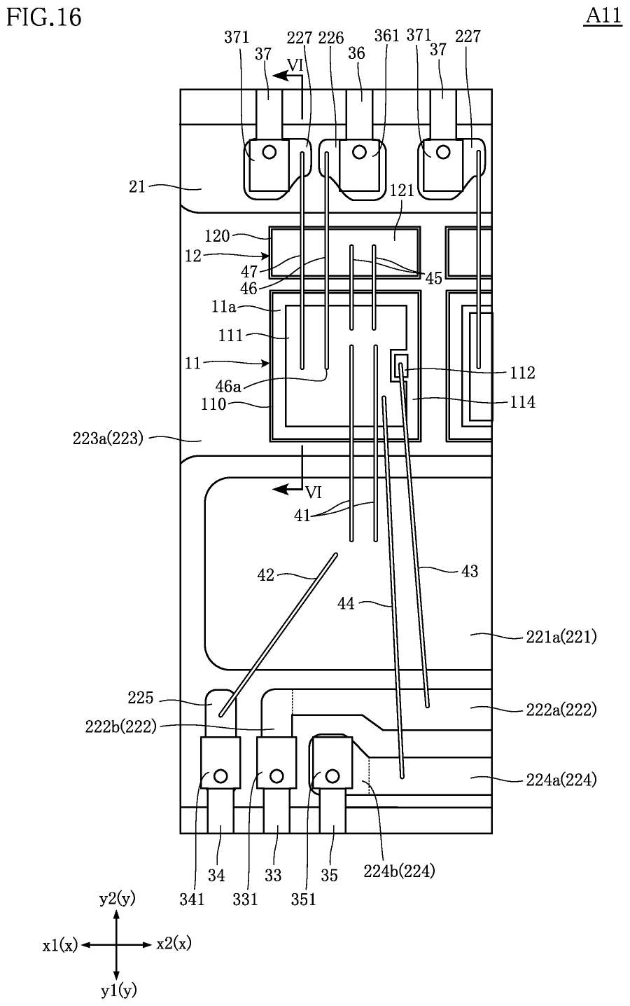

FIGS. 16 to 19 show a variation of the semiconductor device A10 according to the first embodiment. In these figures, the elements that are identical or similar to those of the above-described embodiment are denoted by the same reference signs as those used for the above-described embodiment, and the descriptions thereof are omitted.

### First Variation:

FIG. 16 shows a semiconductor device A11 according to a first variation of the first embodiment. FIG. 16 is a partially enlarged plan view of the semiconductor device A11 and corresponds to FIG. 3. The resin member 5 is transparent in FIG. 16 for the convenience of understanding. The semiconductor device A11 differs from the semiconductor device A10 in that it does not include the metal plate 19.

According to the present variation, the metal plate 19 is not bonded to the first electrode 111 of each semiconductor element 11. The connecting members 41 and 44 to 47 are bonded to the first electrode 111. Heat generated from the semiconductor element 11 is conducted to the first electrode 111. In the present variation, Al is selected as the second metal that is the constituent material of the connecting member 47, because the constituent material of the first electrode 111 is Al. In the present variation, the junction 46a between the connecting member 46 (Cu) and the first electrode 111 (Al) corresponds to the measuring junction of a thermocouple. The constituent material of the connecting member 47 is not limited. The constituent material of the first electrode 111 may be the same as that of the connecting member 46. In the present variation, the measuring junction (the junction 47a) is in direct contact with the first electrode 111, so that the accuracy of the detected temperature of each semiconductor element 11 is improved as compared with the case where the measuring junction is in contact with the metal plate 19.

### Second Variation:

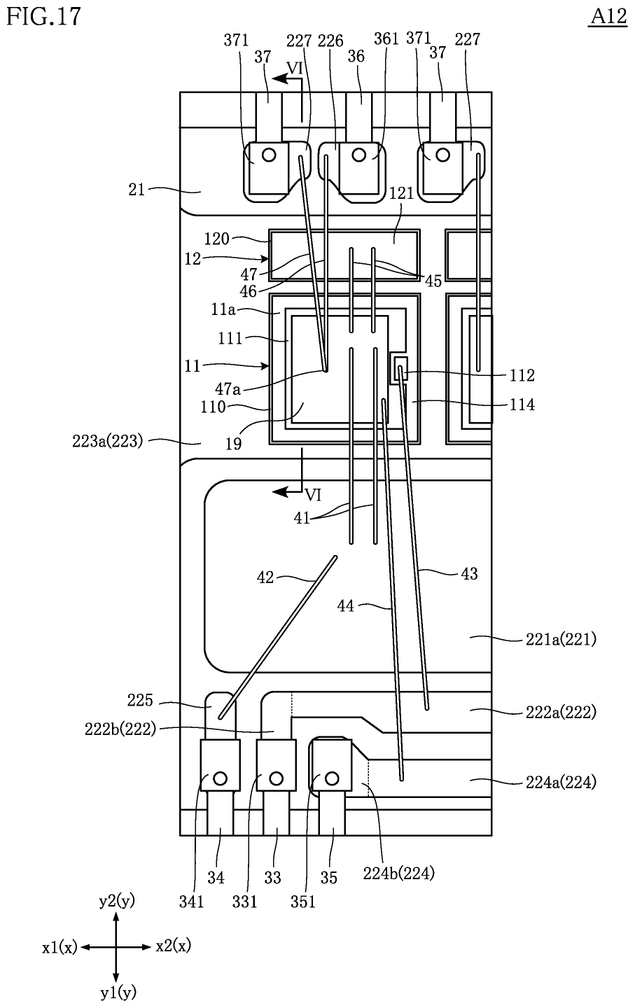

FIG. 17 shows a semiconductor device A12 according to a second variation of the first embodiment. FIG. 17 is a partially enlarged plan view of the semiconductor device A12 and corresponds to FIG. 3. The resin member 5 is transparent in FIG. 17 for the convenience of understanding. The semiconductor device A12 differs from the semiconductor device A10 in that the connecting members 47 are bonded to overlap with the connecting members 46 on the metal plates 19.

In the present variation, each connecting member 47 is bonded onto a connecting member 46 bonded to a metal plate 19. That is, the junction 47a of the connecting member 47, which corresponds to the measuring junction of a thermocouple, is in direct contact with the connecting member 46. According to the present variation, the temperature of each semiconductor element 11 can be detected accurately even when the constituent materials of the connecting member 46 and the connecting member 47 are different from that of the metal plate 19. Thus, in the present variation, the degree of freedom increases in selecting the constituent materials of the connecting members 46 and 47.

### Third Variation:

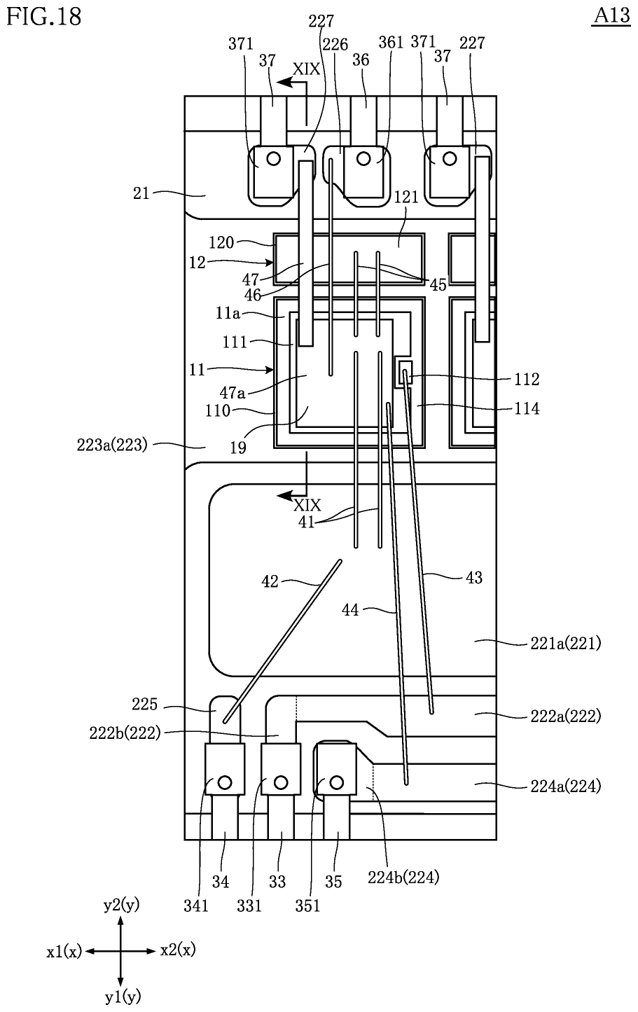

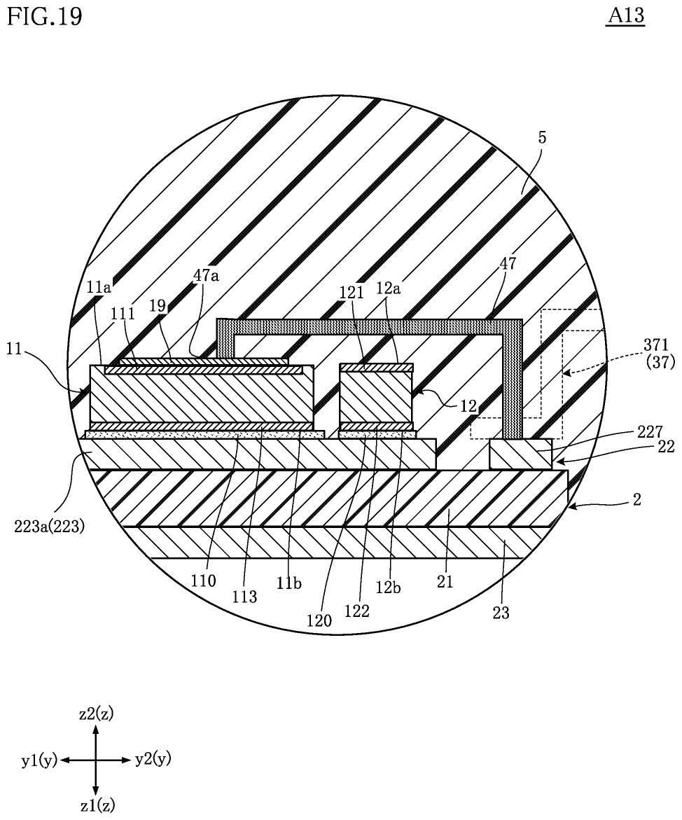

FIGS. 18 and 19 show a semiconductor device A13 according to a third variation of the first embodiment. FIG. 18 is a partially enlarged plan view of the semiconductor device A13 and corresponds to FIG. 3. The resin member 5 is transparent in FIG. 18 for the convenience of understanding. FIG. 19 is a sectional view taken along line XIX-XIX in FIG. 18. The semiconductor device A13 differs from the semiconductor device A10 in configuration of the connecting members 47.

In the present variation, the connecting members 47 are not bonding wires but connecting leads. Each connecting member 47 is a plate-like conductor formed by bending a metal plate. The shape and thickness of the connecting members 47 are not limited. The constituent material of the connecting members 47 is the second metal (constantan). Each connecting member 47 is bonded at one end to a metal plate 19 via a conductive bonding material such as solder, not shown, and bonded at the other end to a conductor layer 227 via a conductive bonding material. The method for bonding the connecting member 47 is not limited and may be bonding using a conductive bonding material such as sintered metal or metal paste, ultrasonic bonding, solid-phase diffusion bonding, laser welding, or spot welding, for example. The present variation is particularly effective when, for example, the constituent material of the connecting members 47 is not suitable for the formation by wire bonding.

Various parts of the first through the third variations may be selectively used in the first embodiment in an any appropriate combination.

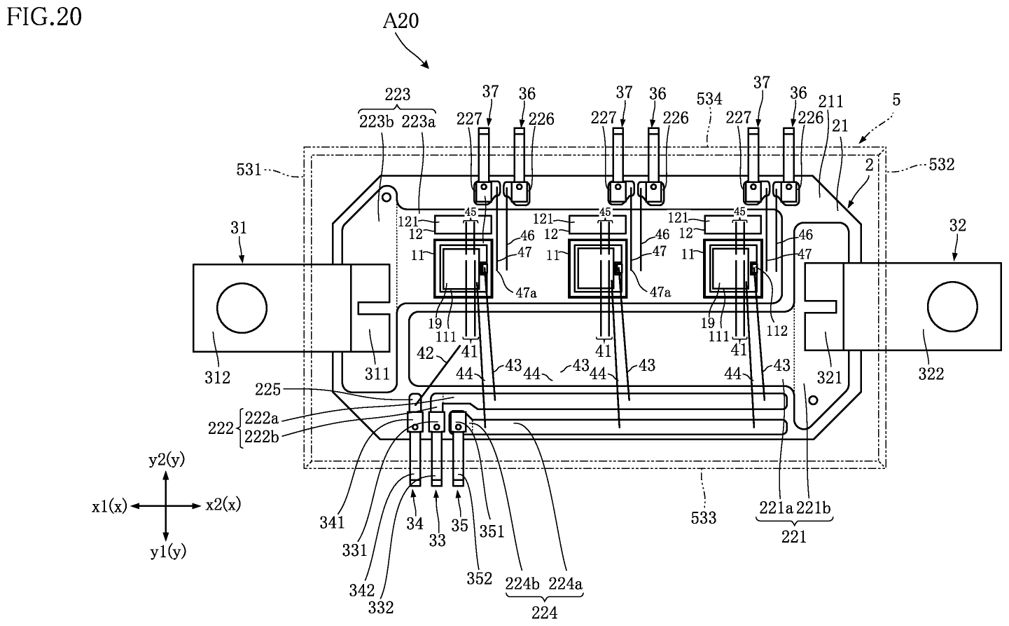

FIGS. 20 to 28 show other embodiments of the present disclosure. In these figures, the elements that are identical or similar to those of the above-described embodiment are denoted by the same reference signs as those used for the above-described embodiment, and the descriptions thereof are omitted.

### Second Embodiment

FIG. 20 shows a semiconductor device A20 according to a second embodiment of the present disclosure. FIG. 20 is a plan view of the semiconductor device A20 and corresponds to FIG. 2. For the convenience of understanding, FIG. 20 shows the resin member 5 as transparent, indicating the outlines of the resin member 5 imaginary (double dashed lines). The by lines semiconductor device A20 according to the present embodiment differs from the semiconductor device A10 according to the first embodiment in that the connecting members 46 and 47 are bonded to the obverse metal layer 22. The configuration and operation of other parts of the present embodiment are the same as the first embodiment. Note that various parts of the first embodiment and the variations may be selectively used in an any appropriate combination.

The semiconductor device A20 according to the present embodiment includes three each of the semiconductor elements 11, the semiconductor elements 12, the temperature detection terminals 36, the temperature detection terminals 37, the conductor layers 226 and the conductor layers 227. Note that the number of these components is not limited. In the present embodiment, one end of each of the connecting members 46 and 47 is not bonded to a metal plate 19 but is bonded to the obverse metal layer 22. Specifically, one end of each of the connecting members 46 and 47 is bonded to the strip portion 223a of the conductor layer 223 at a location adjacent to a semiconductor element 11. Since each semiconductor element 11 is bonded to the strip portion 223a, heat from each semiconductor element 11 is properly conducted to the strip portion 223a via the conductive bonding material 110. Therefore, the temperature of each semiconductor element 11 can be detected by detecting the temperature at a location adjacent to the semiconductor element on the strip portion 223a.

According to the present embodiment, one end of each of the connecting members 46 and 47 is bonded to the strip portion 223a of the conductor layer 223 at a location adjacent to a semiconductor element 11. The strip portion 223a is made of the same metal as the connecting members 46. Thus, a connecting member 46 and the strip portion 223a together with a connecting member 47 function as a thermocouple and can detect a temperature by using the junction 47a between the connecting member 47 and the strip portion 223a as a measuring junction of the thermocouple. The junction 47a is in contact with a portion of the strip portion 223a which is adjacent to the semiconductor element 11 and to which heat from the semiconductor element is properly conducted. Thus, the semiconductor device A20 can detect the temperature of each semiconductor element 11 more accurately as compared with the case where a temperature sensor is disposed near the semiconductor element 11 on the insulating substrate 21. Thus, the semiconductor device A20 can improve the accuracy of the detected temperature of the semiconductor elements 11 without forming a temperature sensor inside each semiconductor element 11. The semiconductor device A20 has a configuration in common with the semiconductor device A10, thereby achieving the same effect as the semiconductor device A10. The present embodiment is particularly effective when, for example, the first electrodes 111 of the semiconductor elements 11 are small and bonding connecting members 46 and 47 to the metal plates is difficult.

### Third Embodiment

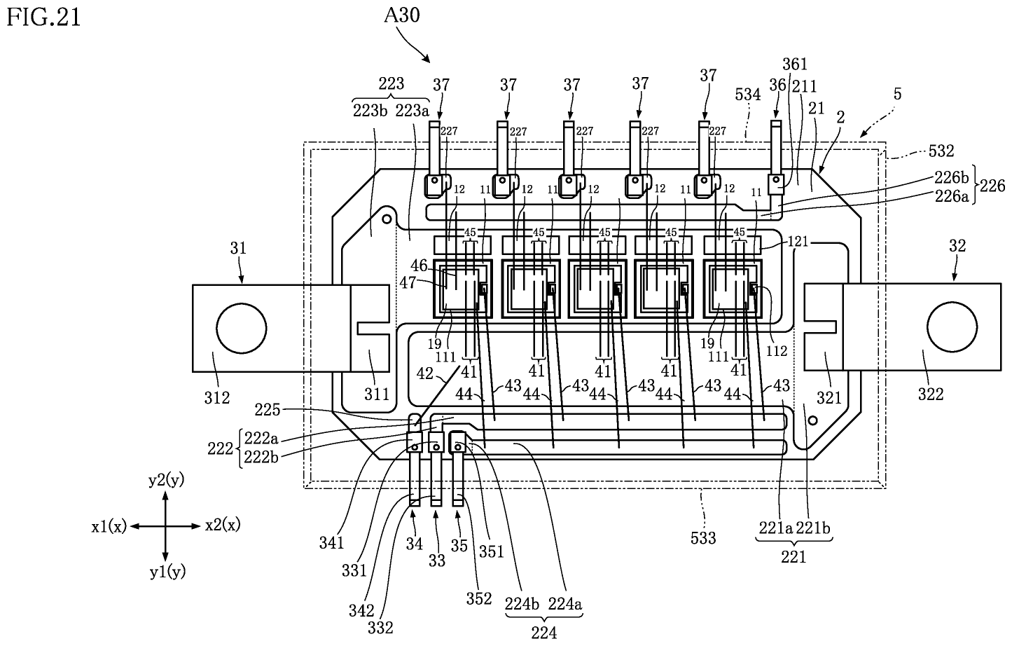

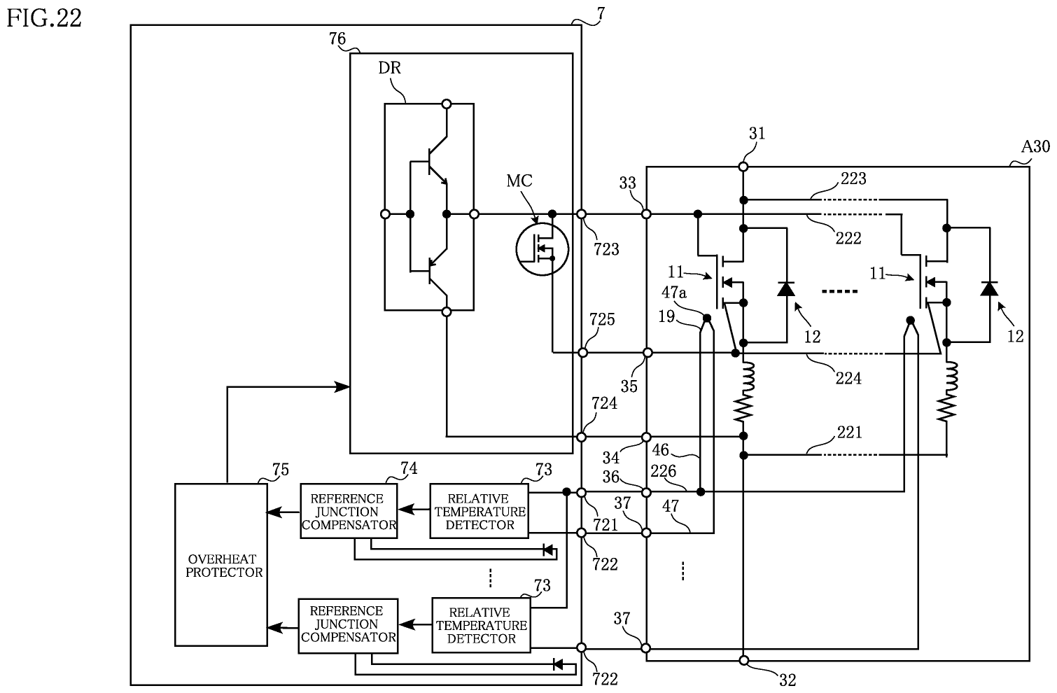

FIGS. 21 and 22 show a semiconductor device A30 according to a third embodiment of the present disclosure. FIG. 21 is a plan view of the semiconductor device A30 and corresponds to FIG. 2. For the convenience of understanding, FIG. 21 shows the resin member 5 as transparent, indicating the outlines of the resin member 5 by imaginary lines (double dashed lines). FIG. 22 is a circuit diagram showing an example of the circuit configuration of the semiconductor device A30 and corresponds to FIG. 8. The semiconductor device A30 according to the present embodiment differs from the semiconductor device A10 according to the first embodiment in number of temperature detection terminals 36, and number, shape, arrangement of layers 2 conductor 226. The configuration and operation of other parts of the present embodiment are the same as the first embodiment. Note that various parts of the first and the second embodiments and the variations may be selectively used in an any appropriate combination.

The semiconductor device A30 according to the present embodiment includes only one temperature detection terminal 36. The temperature detection terminal 36 is used as a common one terminal for the detecting the temperatures of the plurality of semiconductor elements 11. The conductor layer 226 according to the present embodiment includes a strip portion 226a and a terminal bond portion 226b. The strip portion 226a extends along the x direction and is disposed between the strip portion 223a of the conductor layer 223 and the conductor layers 227 in the y direction. Each of the connecting members 46 is bonded to the strip portion 226a. The terminal bond portion 226b is connected to an end of the strip portion 226a on the x2 side in the x direction, and the pad portion 361 of the temperature detection terminal 36 is bonded to the terminal bond portion. A voltage corresponding to the relative temperature of each semiconductor element 11 is outputted from the temperature detection terminal 36 and the temperature detection terminal 37 corresponding to the semiconductor element 11. The voltage corresponding to the relative temperature of the semiconductor element 11 is inputted to the drive device 7 as a voltage between a terminal 721 and a terminal 722.

In the present embodiment again, each semiconductor element 11 has a metal plate 19 bonded to the first electrode 111, and the connecting members 46 and 47 are bonded to the metal plate 19 at their one ends. A connecting member 46 and a metal plate 19 together with a connecting member 47 function as a thermocouple, and can detect a temperature by using the junction 47a between the connecting member 47 and the metal plate 19 as a measuring junction of the thermocouple. Thus, the semiconductor device A30 can improve the accuracy of the detected temperature of the semiconductor elements 11 without forming a temperature sensor inside each semiconductor element 11. The semiconductor device A30 has a configuration in common with the semiconductor device A10, thereby achieving the same effect as the semiconductor device A10. The present embodiment advantageously reduces the number of temperature detection terminals 36 disposed in the semiconductor device A30.

### Fourth Embodiment

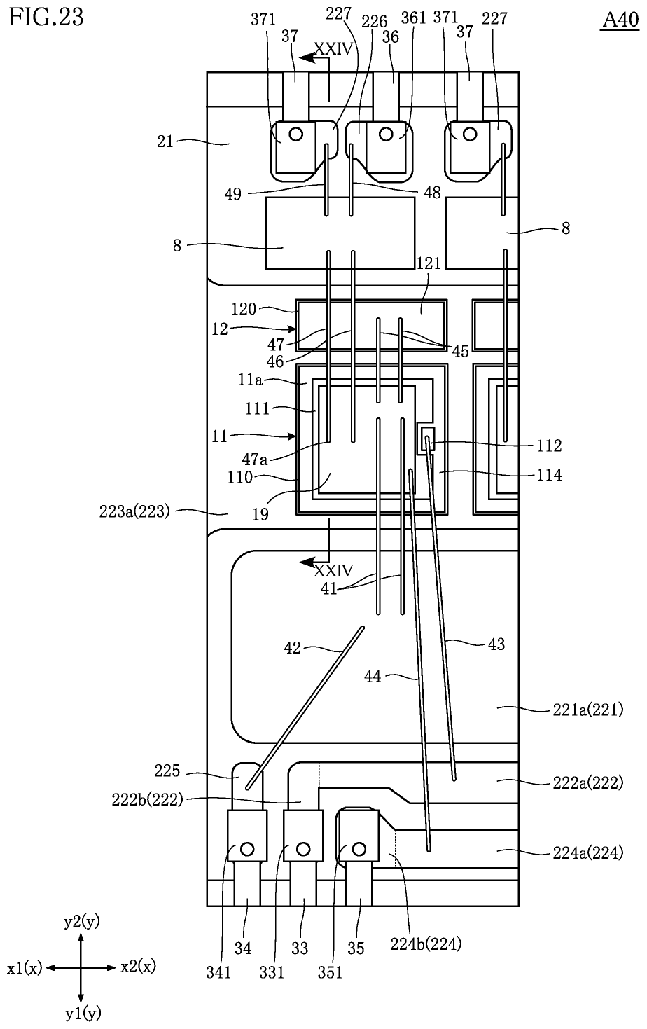

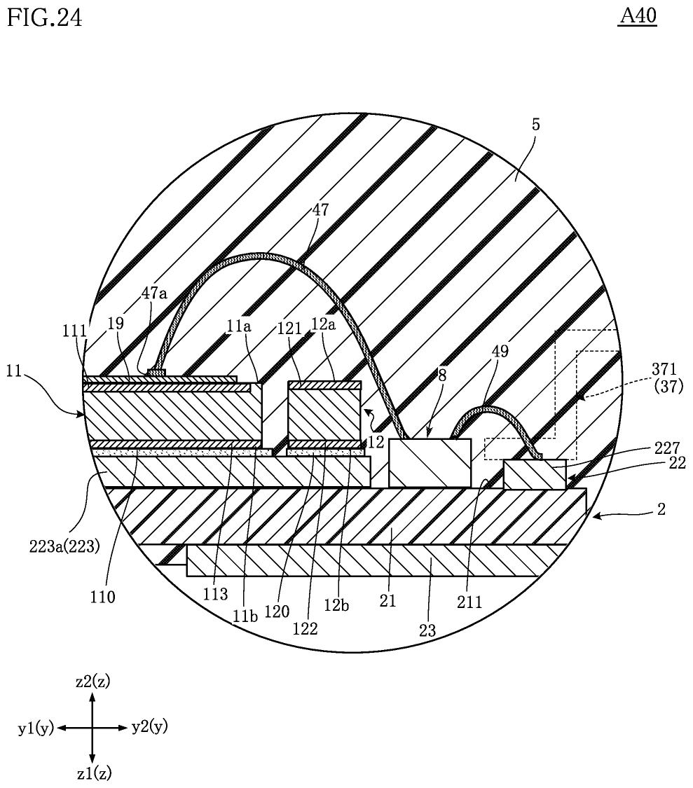

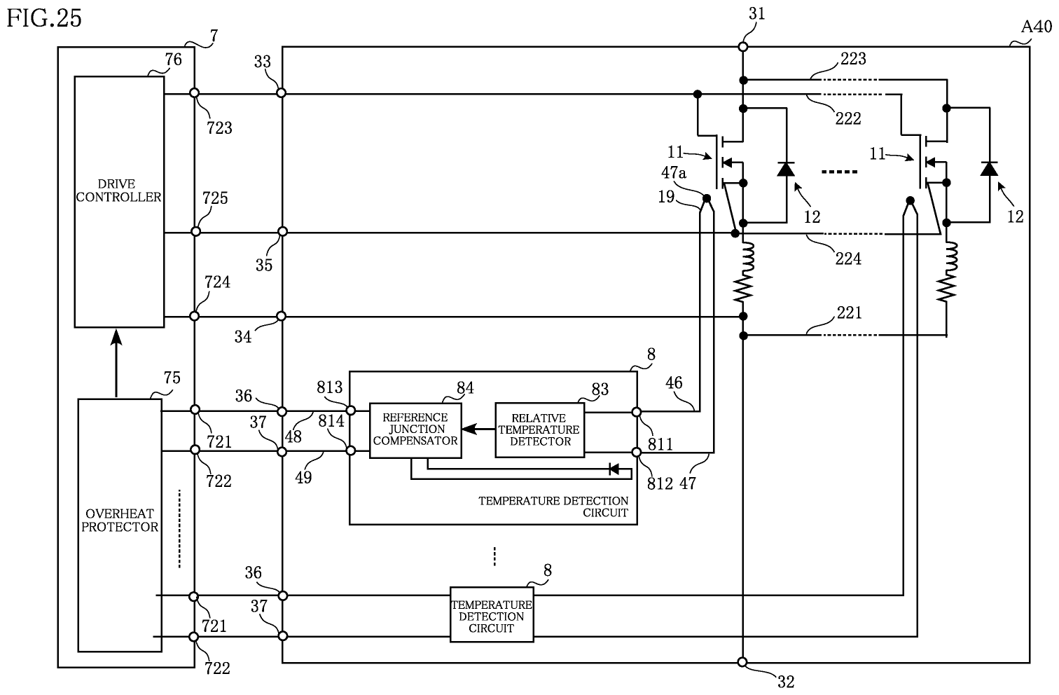

FIGS. 23 to 25 show a semiconductor device A40 according to a fourth embodiment of the present disclosure. FIG. 23 is a partially enlarged plan view of the semiconductor device A40 and corresponds to FIG. 3. The resin member 5 is transparent in FIG. 23 for the convenience of understanding. FIG. 24 is a sectional view taken along line XXIV-XXIV in FIG. 23. FIG. 25 is a circuit diagram showing an example of the circuit configuration of the semiconductor device A40 and corresponds to FIG. 8. The semiconductor device A40 according to the present embodiment differs from the semiconductor device A10 according to the first embodiment in that it further includes temperature detection circuits 8. The configuration and operation of other parts of the present embodiment are the same as the first embodiment. Note that various parts of the first through the third embodiments and the variations may be selectively used in an any appropriate combination.

In the present embodiment, the semiconductor device A40 further includes a plurality of temperature detection circuits 8, a plurality of connecting members 48, and a plurality of connecting members 49. In the present embodiment, the drive device 7 does not include the relative temperature detector 73 and the reference junction compensator 74, and the semiconductor device A40 internally has the temperature detection circuits 8 having the same function as the relative temperature detector 73 and the reference junction compensator 74.

Five temperature detection circuits 8, which are ICs, are provided to correspond to the number of semiconductor elements 11. As shown in FIGS. 23 and 24, the temperature detection circuits 8 are bonded to the obverse surface 211 of the insulating substrate 21 on the y2 side in the y direction of the strip portion 223a of the conductor layer 223 and on the y1 side in the y direction of the conductor layers 226 and 227 with a bonding material, not shown. Each temperature detection circuit 8 is located between a corresponding semiconductor element 11 and temperature detection terminals 36 and 37 in the y direction. In the present embodiment, one end of each connecting member 46 is bonded to a temperature detection circuit 8 (the terminal 811, described later), not to the conductor layer 226. Also, one end of each connecting member 47 is bonded to a temperature detection circuit 8 (the terminal 812, described later), not to the conductor layer 227. Each connecting member 48 is bonded to a temperature detection circuit 8 (the terminal 813, described later) at one end and bonded to a conductor layer 226 at the other end. Each connecting member 49 is bonded to a temperature detection circuit 8 (the terminal 814, described later) at one end and bonded to a conductor layer 227 at the other end. The constituent materials of the connecting members 47 and 48 are the same as that of the connecting members 41 to 45, but are not limited.

Each temperature detection circuit 8 includes a relative temperature detector 83, a reference junction compensator 84, and terminals 811 to 814. To the terminal 811 is bonded a connecting member 46. To the terminal 812 is bonded a connecting member 47. To the terminal 813 is bonded a connecting member 48. The terminal 813 is electrically connected to a temperature detection terminal 36 via the connecting member 48 and a conductor layer 226. To the terminal 814 is bonded a connecting member 49. The terminal 814 is electrically connected to a temperature detection terminal 37 via the connecting member 49 and a conductor layer 227.

The relative temperature detector 83 has the same function as the relative temperature detector 73. The relative temperature detector 83 receives a voltage from the terminal 811 and the terminal 812 to detect the relative temperature of the corresponding semiconductor element 11. The reference junction compensator 84 has the same function as the reference junction compensator 74. The reference junction compensator 84 converts the relative temperature detected by the relative temperature detector 83 into an absolute temperature. The reference junction compensator 84 is provided with a temperature detecting part having e.g. a diode disposed adjacent to the terminals 811 and 812. The reference junction compensator 84 adds the temperature of the reference junctions detected by the temperature detecting part to the relative temperature detected by the relative temperature detector 83, thereby converting the relative temperature into an absolute temperature. The reference junction compensator 84 outputs the voltage corresponding to the absolute temperature of the corresponding semiconductor element 11 through the terminals 813 and 814. The specific circuit configuration and mode of the temperature detection circuits 8 are not limited.

The temperature detection terminals 36 and 37 outputs the voltage corresponding to the absolute temperature of the semiconductor element 11 to the overheat protector 75 through the terminals 721 and 722 of the drive device 7. Therefore, a conventional drive device with an overheat protection function based on inputted absolute temperatures can be used as the drive device 7 of the present embodiment.

In the present embodiment again, each semiconductor element 11 has a metal plate 19 bonded to the first electrode 111, and the connecting members 46 and 47 are bonded to the metal plate 19 at their one ends. A connecting member 46 and a metal plate 19 together with a connecting member 47 function as a thermocouple, and can detect a temperature by using the junction 47a between the connecting member 47 and the metal plate 19 as a measuring junction of the thermocouple. Thus, the semiconductor device A40 can improve the accuracy of the detected temperature of the semiconductor elements 11 without forming a temperature sensor inside each semiconductor element 11. The semiconductor device A40 has a configuration in common with the semiconductor device A10, thereby achieving the same effect as the semiconductor device A10. Moreover, the semiconductor device A40 according to the present embodiment includes the temperature detection circuits 8 each having a relative temperature detector 83 and a reference junction compensator 84. Thus, the semiconductor device A40 can convert the detected relative temperatures of the semiconductor elements 11 into absolute temperatures and output them to the drive device 7. Therefore, the semiconductor device A40 can use, as the drive device 7, a conventional drive device with an overheat protection function based on inputted absolute temperatures.

### Fifth Embodiment

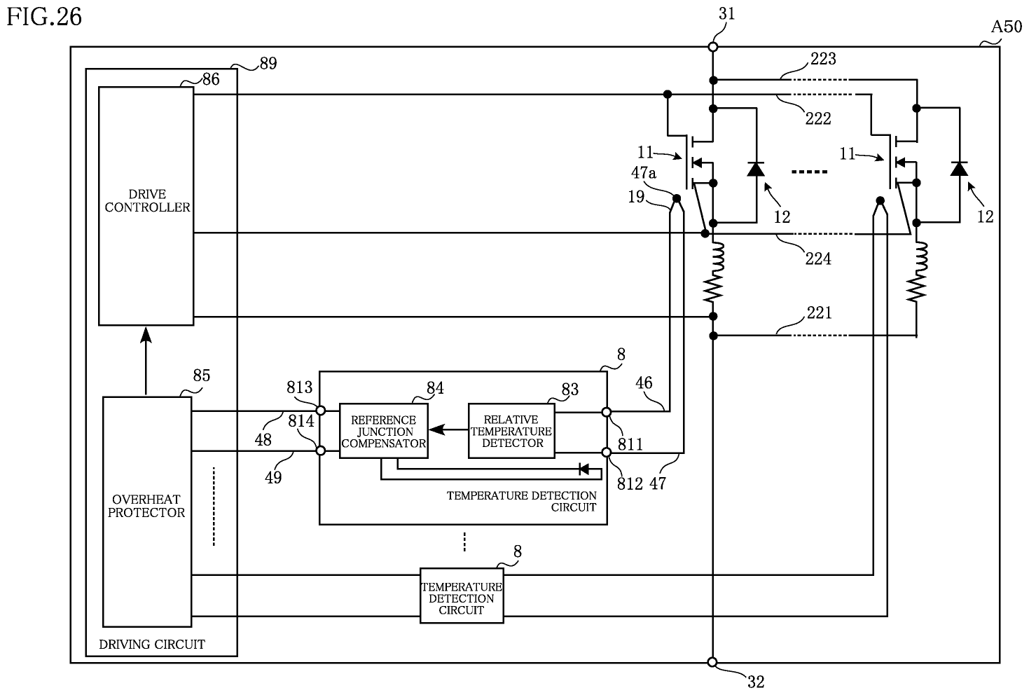

FIG. 26 shows a semiconductor device A50 according to a fifth embodiment of the present disclosure. FIG. 26 is a circuit diagram showing an example of the circuit configuration of the semiconductor device A50 and corresponds to FIG. 8. The semiconductor device A50 according to the present embodiment differs from the semiconductor device A10 according to the first embodiment in that it further includes temperature detection circuits 8 and a driving circuit 89. The configuration and operation of other parts of the present embodiment are the same as the first embodiment. Note that various parts of the first through the fourth embodiments and the variations may be selectively used in an any appropriate combination.

In the present embodiment, the semiconductor device A50 further includes a driving circuit 89, a plurality of temperature detection circuits 8, a plurality of connecting members 48, and a plurality of connecting members 49. In the present embodiment, the semiconductor device A50 internally has the function of the drive device 7 according to the first embodiment. The temperature detection circuits 8 are the same as the temperature detection circuits 8 of the fourth embodiment. The terminal 813 of each temperature detection circuit 8 is electrically connected to the driving circuit 89 (the overheat protector 85, described later) with a connecting member 48. The terminal 814 of each temperature detection circuit 8 is electrically connected to the driving circuit 89 (the overheat protector 85, described later) with a connecting member 49.

The driving circuit 89 may be an IC, for example, and has the same function as the drive device 7 of the fourth embodiment. The driving circuit 89 includes an overheat protector 85 and a drive controller 86. The drive controller 86 has the same function as the drive controller 76 of the fourth embodiment (i.e., the drive controller 76 of the first embodiment). That is, the drive controller 86 generates a drive signal based on a control signal inputted from the outside to control the switching operation of each semiconductor element 11. Also, the drive controller 86 receives a detection signal of a voltage of the first electrode 111 (the source electrode) of each semiconductor element 11. The overheat protector 85 has the same function as the overheat protector 75 of the fourth embodiment (i.e., the overheat protector 75 of the first embodiment). That is, the overheat protector 85 receives a voltage corresponding to the absolute temperature of a semiconductor element 11 from each temperature detection circuit 8 to detect the overheating or abnormal temperature. The specific circuit configuration and mode of the driving circuit 89 are not limited.

In the present embodiment again, each semiconductor element 11 has a metal plate 19 bonded to the first electrode 111, and the connecting members 46 and 47 are bonded to the metal plate 19 at their one ends. A connecting member 46 and a metal plate 19 together with a connecting member 47 function as a thermocouple, and can detect a temperature by using the junction 47a between the connecting member 47 and the metal plate 19 as a measuring junction of the thermocouple. Thus, the semiconductor device A50 can improve the accuracy of the detected temperature of the semiconductor elements 11 without forming a temperature sensor inside each semiconductor element 11. The semiconductor device A50 has a configuration in common with the semiconductor device A10, thereby achieving the same effect as the semiconductor device A10. Moreover, the semiconductor device A50 according to the present embodiment includes the temperature detection circuits 8 each having a relative temperature detector 83 and a reference junction compensator 84, and a driving circuit 89 having the overheat protector 85 and the drive controller 86. Thus, the semiconductor device A50 is capable of converting the detected relative temperatures of the semiconductor elements 11 into absolute temperatures to protect the semiconductor elements 11 from overheating.

### Sixth Embodiment

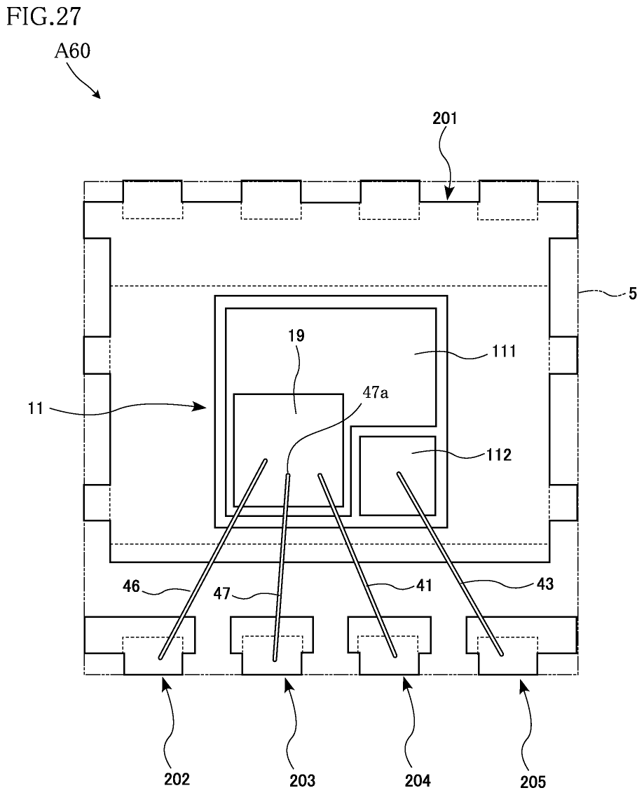

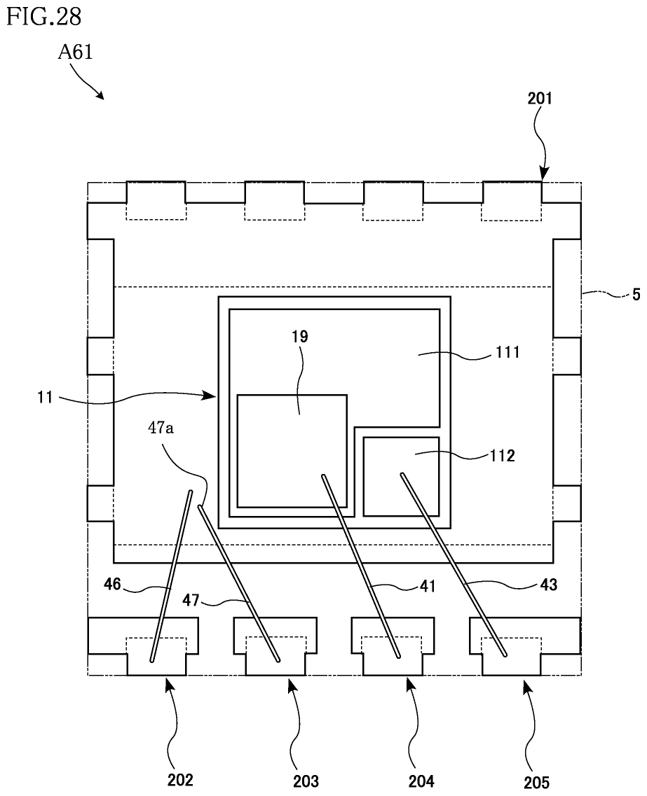

FIG. 27 shows a semiconductor device A60 according to a sixth embodiment of the present disclosure. FIG. 27 is a plan view of the semiconductor device A60 and corresponds to FIG. 2. For the convenience of understanding, FIG. 27 shows the resin member 5 as transparent, indicating the outlines of the resin member 5 by imaginary lines (double dashed lines). The semiconductor device A60 according to the present embodiment differs from the semiconductor device A10 in the package type. The configuration and operation of other parts of the present embodiment are the same as the first embodiment. Note that various parts of the first through the fifth embodiments and the variations may be selectively used in an any appropriate combination.

The package type of the semiconductor device A60 is the DEN (Dual Flatpack No-leaded). The semiconductor device A60 includes leads 201 to 205, a semiconductor element 11, a metal plate 19, connecting members 41, 43, 46 and 47, and a resin member 5. The semiconductor element 11, the metal plate 19, the connecting members 41, 43, 46 and 47, and the resin member 5 are the same as the first embodiment.

The leads 201 to 205 are electrically connected to the semiconductor element 11. The leads 201 to 205 are made of a metal, and preferably made of one of Cu and Ni, an alloy of these, or 42 alloy, for example. The constituent material of the leads 201 to 205 is not limited, but is Cu in the present embodiment. The leads 201 to 205 are made of, for example, a lead frame formed by stamping a metal plate.

In the semiconductor element 11, the element reverse surface 11b (not shown) is bonded to the lead 201 via a conductive bonding material 110 (not shown). The third electrode 113 (the drain electrode) (not shown) is electrically connected to the lead 201 via a conductive bonding material 110. The connecting member 41 is bonded at one end to the metal plate 19 bonded to the first electrode 111 (the source electrode) and bonded at the other end to the lead 204. The connecting member 41 electrically connects the first electrode 111 and the lead 204 to each other. The connecting member 43 is bonded at one end to the second electrode 112 (the gate electrode) and bonded at the other end to the lead 205. The connecting member 43 electrically connects the second electrode 112 and the lead 205 to each other. The connecting member 46 is bonded at one end to the metal plate 19 and bonded at the other end to the lead 202. The connecting member 47 is bonded at one end to the metal plate 19 and bonded at the other end to the lead 203. The leads 202 and 203 are the terminals for detecting the temperature of the semiconductor element 11.

In the present embodiment again, the semiconductor element 11 has a metal plate 19 bonded to the first electrode 111, and the connecting members 46 and 47 are bonded to the metal plate 19 at their one ends. The connecting member 46 and the metal plate 19 together with the connecting member 47 function as a thermocouple, and can detect a temperature by using the junction 47a between the connecting member 47 and the metal plate 19 as the measuring junction of the thermocouple. Thus, the semiconductor device A60 can improve the accuracy of the detected temperature of the semiconductor element 11 without forming a temperature sensor inside the semiconductor element 11. The semiconductor device A60 has a configuration in common with the semiconductor device A10, thereby achieving the same effect as the semiconductor device A10.

FIG. 28 shows a variation of the semiconductor device A60 according to the sixth embodiment. In FIG. 28, the elements that are identical or similar to those of the sixth embodiment are denoted by the same reference signs as those used for the above-described embodiments, and the descriptions thereof are omitted. FIG. 28 shows a semiconductor device A61 according to a first variation of the sixth embodiment. FIG. 28 is a plan view of the semiconductor device A61 and corresponds to FIG. 27. The resin member 5 is transparent in FIG. 28 for the convenience of understanding. The semiconductor device A61 differs from the semiconductor device A60 in that the connecting members 46 and 47 are bonded to the lead 201.

According to the present variation, one end of each of the connecting members 46 and 47 is bonded to the lead 201 at a location adjacent to the semiconductor element 11, not to the metal plate 19. Since the semiconductor element 11 is bonded to the lead 201, heat from the semiconductor element 11 is properly conducted to the lead 201 via the conductive bonding material 110. Therefore, the temperature of the semiconductor element 11 can be detected by detecting the temperature at a location adjacent to the semiconductor element 11 on the lead 201.

The semiconductor device, the drive device, and the method for manufacturing the semiconductor device according to the present disclosure are not limited to the above-described embodiments. Various modifications in design may be made freely in the specific structure of each part of the semiconductor device and the drive device according to the present disclosure and in the specific processing in each step of the method for manufacturing the semiconductor device according to the present disclosure.

Clause 1.

A semiconductor device comprising:
a semiconductor element (11) including an element obverse surface (11a) and an element reverse surface (11b) facing away from each other in a thickness direction, and an electrode (111) disposed on the element obverse surface;
a first wire (46) containing a first metal;
a second wire (47) containing a second metal having thermoelectric power different from the first metal; and
a metal portion (19, 111, 223a, 201) containing a third metal and disposed such that heat from the semiconductor element is conducted thereto, the first wire and the second wire being bonded to the metal portion,
wherein at least one of the first wire and the second wire is directly bonded to the metal portion.

Clause 2.

The semiconductor device according to clause 1, wherein the third metal is a same metal as the first metal.

Clause 3.

The semiconductor device according to clause 1 or 2, wherein the first wire and the second wire are bonded to the metal portion in a mutually spaced manner.

Clause 4.

The semiconductor device according to any one of clauses 1 to 3, wherein each of the first wire and the second wire is directly bonded to the metal portion.

Clause 4-1.

The semiconductor device according to clause 1 or 2, wherein the first wire is directly bonded to the metal portion, and the second wire is directly bonded to the first wire.

Clause 5.

The semiconductor device according to any one of clauses 1 to 4, further comprising a metal plate (19) bonded to the electrode,
wherein the metal portion is the metal plate.

Clause 6. (The first variation of the first embodiment, FIG. 16)

The semiconductor device according to any one of clauses 1 to 4, wherein the metal portion is the electrode.

Clause 7. (The first variation of the sixth embodiment, FIG. 28)

The semiconductor device according to any one of clauses 1 to 4, further comprising a first lead (201), the element reverse surface of the semiconductor element being bonded to the first lead,
wherein the metal portion is the first lead.

Clause 8. (Second Embodiment, FIG. 20)

The semiconductor device according to any one of clauses 1 to 4, further comprising:
an insulating substrate (21) on which the semiconductor element is mounted; and
a metal layer (223) which is disposed on the substrate and to which the element reverse surface of the semiconductor element is bonded,
wherein the metal portion is the metal layer.

Clause 9.

The semiconductor device according to any one of clauses 1 to 8, wherein the first metal is Cu, and
the second metal is constantan.

Clause 10.

The semiconductor device according to any one of clauses 1 to 8, wherein the first metal is Cu, and the second metal is Al.

Clause 11. (The fourth Embodiment, FIGS. 23 to 25)

The semiconductor device according to any one of clauses 1 to 10, further comprising:
a first bond portion (811) to which the first wire is bonded;
a second bond portion (812) to which the second wire is bonded;
a relative temperature detector (83) that detects a relative temperature based on a voltage between the first bond portion and the second bond portion; and
a reference junction compensator (84) that detects a reference temperature of the first bond portion and the second bond portion and calculates an absolute temperature based on the reference temperature and the relative temperature.

Clause 12. (The fifth Embodiment, FIG. 26)

The semiconductor device according to clause 11, further comprising a driving circuit (89) that drives the semiconductor element,
wherein the driving circuit includes an overheat protector (85) that detects overheating or abnormal temperature of the semiconductor element based on the absolute temperature.

Clause 13. (The first Embodiment, FIG. 8)

A drive device (7) for driving the semiconductor device as set forth in any one of clauses 1 to 10, the drive device comprising:
a first terminal (721) electrically connected to the first wire;
a second terminal (722) electrically connected to the second wire;
a relative temperature detector (73) that detects a relative temperature based on a voltage between the first terminal and the second terminal;
a reference junction compensator (74) that detects a reference temperature of the first terminal and the second terminal and calculates an absolute temperature based on the reference temperature and the relative temperature; and an overheat protector (75) that detects overheating or abnormal temperature of the semiconductor element based on the absolute temperature.

Clause 14. (FIG. 9)

A method for manufacturing a semiconductor device, the method comprising:
a step (S41) of bonding a first wire containing a first metal to a metal portion containing a third metal, the metal portion being disposed such that heat from a semiconductor element is conducted thereto; and
a step (S42) of bonding a second wire containing a second metal having a thermoelectric power different from the first metal to the metal portion.

Clause 15.

The method for manufacturing a semiconductor device according to clause 14, further comprising:
before the step of bonding the first wire,
a step (S12) of forming a metal layer on an insulating substrate; and
a step (S3) of bonding the semiconductor element having a metal plate bonded thereto to the metal layer, the metal plate being the metal portion.

### REFERENCE NUMERALS

A10, A11, A12, A13, A20: Semiconductor device
A30, A40, A50, A60, A61: Semiconductor device
11, 12: Semiconductor element 11a, 12a: Element obverse surface
11b, 12b: Element reverse surface
110, 120: Conductive bonding material
111: First electrode 112: Second electrode
113: Third electrode 121: Anode electrode
122: Cathode electrode 19: Metal plate
2: Support member 21: Insulating substrate
211: Obverse surface 212: Reverse surface
22: Obverse metal layer
221, 222, 223, 224, 225, 226, 227: Conductor layer
221a, 222a, 223a, 224a, 226a: Strip portion
221b, 222b, 223b, 224b, 226b: Terminal bond portion
23: Reverse metal layer 201 to 205: Lead
3: Terminal 31, 32: Power terminal
33: Signal terminal 34, 35: Detection terminal
36, 37: Temperature detection terminal
311, 321, 331, 341, 351, 361, 371: Pad portion
312, 322, 332, 342, 352, 362, 372: Terminal portion
41 to 49: Connecting member 46a, 47a: Junction
5: Resin member 51: Resin obverse surface
52: Resin reverse surface 531, 532, 533, 534: Resin side surface
7: Drive device 71: Substrate
711: Obverse surface 712: Reverse surface
721 to 725: Terminal 73: Relative temperature detector
74: Reference junction compensator 75: Overheat protector
76: Drive controller 8: Temperature detection circuit
811 to 814: Terminal 83: Relative temperature detector
84: Reference junction compensator
86: Drive controller 85: Overheat protector
91: Insulating substrate 89: Driving circuit
911: Obverse surface 912: Reverse surface
92: Lead frame 93: Conductive bonding paste
DR: Drive circuit MC: Mirror clamp circuit

1. A semiconductor device comprising:
a semiconductor element including an element obverse surface and an element reverse surface facing away from each other in a thickness direction, and an electrode disposed on the element obverse surface;
a first wire containing a first metal;
a second wire containing a second metal having thermoelectric power different from the first metal; and
a metal portion containing a third metal and disposed such that heat from the semiconductor element is conducted thereto, the first wire and the second wire being bonded to the metal portion,
wherein at least one of the first wire and the second wire is directly bonded to the metal portion.

2. The semiconductor device according to claim 1, wherein the third metal is a same metal as the first metal.

3. The semiconductor device according to claim 1, wherein the first wire and the second wire are bonded to the metal portion in a mutually spaced manner.

4. The semiconductor device according to claim 1, wherein each of the first wire and the second wire is directly bonded to the metal portion.

5. The semiconductor device according to claim 1, further comprising a metal plate bonded to the electrode,
wherein the metal portion is the metal plate.

6. The semiconductor device according to claim 1, wherein the metal portion is the electrode.

7. The semiconductor device according to claim 1, further comprising a first lead, the element reverse surface of the semiconductor element being bonded to the first lead,
wherein the metal portion is the first lead.

8. The semiconductor device according to claim 1, further comprising:
an insulating substrate on which the semiconductor element is mounted; and
a metal layer which is disposed on the substrate and to which the element reverse surface of the semiconductor element is bonded,
wherein the metal portion is the metal layer.

9. The semiconductor device according to claim 1, wherein the first metal is Cu, and
the second metal is constantan.

10. The semiconductor device according to claim 1, wherein the first metal is Cu, and
the second metal is Al.

11. The semiconductor device according to claim 1, further comprising:
a first bond portion to which the first wire is bonded;
a second bond portion to which the second wire is bonded;
a relative temperature detector that detects a relative temperature based on a voltage between the first bond portion and the second bond portion; and
a reference junction compensator that detects a reference temperature of the first bond portion and the second bond portion and calculates an absolute temperature based on the reference temperature and the relative temperature.

12. The semiconductor device according to claim 11, further comprising a driving circuit that drives the semiconductor element,
wherein the driving circuit includes an overheat protector that detects overheating or abnormal temperature of the semiconductor element based on the absolute temperature.

13. A drive device for driving the semiconductor device as set forth in claim 1, the drive device comprising:
a first terminal electrically connected to the first wire;
a second terminal electrically connected to the second wire;
a relative temperature detector that detects a relative temperature based on a voltage between the first terminal and the second terminal;
a reference junction compensator that detects a reference temperature of the first terminal and the second terminal and calculates an absolute temperature based on the reference temperature and the relative temperature; and
an overheat protector that detects overheating or abnormal temperature of the semiconductor element based on the absolute temperature.

14. A method for manufacturing a semiconductor device, the method comprising:
bonding a first wire containing a first metal to a metal portion containing a third metal, the metal portion being disposed such that heat from a semiconductor element is conducted thereto; and
bonding a second wire containing a second metal having a thermoelectric power different from the first metal to the metal portion.

15. The method for manufacturing a semiconductor device according to claim 14, further comprising:
before the bonding of the first wire,
forming a metal layer on an insulating substrate; and
bonding the semiconductor element having a metal plate bonded thereto to the metal layer, the metal plate being the metal portion.
